(19) United States
(12) Patent Application Publication
(10) Pub. No.: US 2016/0064507 A1
(43) Pub. Date: Mar. 3, 2016

(54) SEMICONDUCTOR DEVICE AND METHOD OF MANUFACTURING SAME

(71) Applicant: Rensas Electronics Corporation, Tokyo (JP)

(72) Inventor: Atsushi Amo, Tokyo (JP)

(73) Assignee: RENESAS ELECTRONICS CORPORATION

(21) Appl. No.: 14/828,477

(22) Filed: Aug. 17, 2015

(30) Foreign Application Priority Data
Aug. 29, 2014 (JP) 2014-174823

(51) Int. Cl. H01L 29/49; H01L 29/51; H01L 27/115

(52) U.S. Cl. CPC H01L 29/4975; H01L 27/11521; H01L 27/11568; H01L 29/518; H01L 29/517

(57) ABSTRACT

To provide a semiconductor device having a memory cell equipped with a control gate electrode and a memory gate electrode adjacent to each other via a charge storage layer and having improved performance.

In a semiconductor device having a MISFET including a gate electrode which is a metal gate electrode formed by a so-called gate last process, a control gate electrode and a memory gate electrode which include a memory cell of a split-gate type MONOS memory are formed by fully siliciding a silicon film.

### CROSS-REFERENCE TO RELATED APPLICATIONS

The disclosure of Japanese Patent Application No. 2014-174823 filed on Aug. 29, 2014 including the specification, drawings, and abstract is incorporated herein by reference in its entirety.

### BACKGROUND

The present invention relates to a semiconductor device and a method of manufacturing same and it can be used for, for example, the manufacture of a semiconductor device having a nonvolatile memory.

As an electrically writable/erasable nonvolatile semiconductor memory device, an EEPROM (electrically erasable and programmable read only memory) has been used widely. Such widely used memory devices typified by a flash memory have, below a gate electrode of a MISFET thereof, a conductive floating gate electrode or a trapping insulating film surrounded by an oxide film. Charges stored in the floating gate or trapping insulating film as memory information are read as the threshold value of the transistor. The trapping insulating film is a film capable of storing therein charges and a silicon nitride film is one example of it. The threshold value of the MISFET is shifted by injection/emission of charges to/from a charge storage region and thus, it is operated as a memory element. As an example of the nonvolatile semiconductor memory device using the trapping insulating film, a split-gate type cell using a MONOS (metal oxide nitride oxide oxide semiconductor) film can be given.

As a gate electrode formation method, known is a so-called gate last process, that is, a process of forming a dummy gate electrode on a substrate and then replacing the dummy gate electrode by a metal gate electrode or the like.

Patent Document 1 (Japanese Unexamined Patent Application Publication No. 2005-228786) describes a nonvolatile semiconductor memory device having a memory cell. The memory cell has a control gate electrode made of a semiconductor film and a fully-silicide memory gate electrode.

[Patent Document 1] Patent Document 1 (Japanese Unexamined Patent Application Publication No. 2005-228786

### SUMMARY

A MONOS memory or MISFET having a gate electrode made of a semiconductor film has such a problem that depletion in the gate electrode during inversion of a channel region deteriorates the drive capacity of the transistor.

When the gate last process is used, there may occur variations in the height of the gate electrode due to a difference in polishing characteristic caused by the material or density of a member to be polished. This may lead to variations in the film thickness of a silicide layer formed on an upper portion of the gate electrode to silicide the upper surface thereof without replacing the gate electrode by a metal gate electrode. This results in variations in the characteristics of the MONOS memory or MISFET.

Another problem and novel features will be apparent from the description herein and accompanying drawings.

The outline of a typical embodiment, among those disclosed herein, will next be described simply.

In one embodiment, there is provided a semiconductor device obtained by forming a control gate electrode and a memory gate electrode, which include a memory cell of a split gate type MONOS memory, of a silicide layer.

In another embodiment, there is also provided a method of manufacturing a semiconductor device including fully siliciding a silicon film to form a control gate electrode and a memory gate electrode which include a memory cell of a split gate type MONOS memory.

According to the embodiments, a semiconductor device having improved performance or having less variations in the characteristics can be provided, or a semiconductor device having both advantages can be provided.

### BRIEF DESCRIPTION OF THE DRAWINGS

FIG. 1 is a cross-sectional view of a semiconductor device of First Embodiment;

FIG. 2 is a schematic plan view of the semiconductor device of First Embodiment;

FIG. 3 is a cross-sectional view of the semiconductor device of First Embodiment during a manufacturing step;

FIG. 4 is a cross-sectional view of the semiconductor device during a manufacturing step following that of FIG. 3;

FIG. 5 is a cross-sectional view of the semiconductor device during a manufacturing step following that of FIG. 4;

FIG. 6 is a cross-sectional view of the semiconductor device during a manufacturing step following that of FIG. 5;

FIG. 7 is a cross-sectional view of the semiconductor device during a manufacturing step following that of FIG. 6;

FIG. 8 is a cross-sectional view of the semiconductor device during a manufacturing step following that of FIG. 7;

FIG. 9 is a cross-sectional view of the semiconductor device during a manufacturing step following that of FIG. 8;

FIG. 10 is a cross-sectional view of the semiconductor device during a manufacturing step following that of FIG. 9;

FIG. 11 is a cross-sectional view of the semiconductor device during a manufacturing step following that of FIG. 10;

FIG. 12 is a cross-sectional view of the semiconductor device during a manufacturing step following that of FIG. 11;

FIG. 13 is a cross-sectional view of the semiconductor device during a manufacturing step following that of FIG. 12;

FIG. 14 is a cross-sectional view of the semiconductor device during a manufacturing step following that of FIG. 13;

FIG. 15 is a cross-sectional view of the semiconductor device during a manufacturing step following that of FIG. 14;

FIG. 16 is a cross-sectional view of the semiconductor device during a manufacturing step following that of FIG. 15;

FIG. 17 is a cross-sectional view of the semiconductor device during a manufacturing step following that of FIG. 16;

FIG. 18 is a cross-sectional view of the semiconductor device during a manufacturing step following that of FIG. 17;

FIG. 19 is a table showing one example of voltage applying conditions to each site of a selected memory cell during “write”, “erase”, and “read”;

FIG. 20 is a cross-sectional view of a first modification example of the semiconductor device of First Embodiment during a manufacturing step;

FIG. 21 is a cross-sectional view of the semiconductor device during a manufacturing step following that of FIG. 20;

FIG. 22 is a cross-sectional view of the semiconductor device during a manufacturing step following that of FIG. 21;

FIG. 23 is a cross-sectional view of the semiconductor device during a manufacturing step following that of FIG. 22;

FIG. 24 is a cross-sectional view of the semiconductor device during a manufacturing step following that of FIG. 23;

FIG. 25 is a cross-sectional view of the semiconductor device during a manufacturing step following that of FIG. 24;

FIG. 26 is a cross-sectional view of the semiconductor device during a manufacturing step following that of FIG. 25;

FIG. 27 is a cross-sectional view of a second modification example of the semiconductor device of First Embodiment during a manufacturing step;

FIG. 28 is a cross-sectional view of the semiconductor device during a manufacturing step following that of FIG. 27;

FIG. 29 is a cross-sectional view of a third modification example of the semiconductor device of First Embodiment;

FIG. 30 is a cross-sectional view of a fourth modification example of the semiconductor device of First Embodiment during a manufacturing step;

FIG. 31 is a cross-sectional view of the semiconductor device during a manufacturing step following that of FIG. 30;

FIG. 32 is a cross-sectional view of the semiconductor device during a manufacturing step following that of FIG. 31;

FIG. 33 is a cross-sectional view of the semiconductor device during a manufacturing step following that of FIG. 32;

FIG. 34 is a cross-sectional view of a fifth modification example of the semiconductor device of First Embodiment;

FIG. 35 is a cross-sectional view of a semiconductor device of Second Embodiment during a manufacturing step thereof;

FIG. 36 is a cross-sectional view of the semiconductor device during a manufacturing step following that of FIG. 35;

FIG. 37 is a cross-sectional view of the semiconductor device during a manufacturing step following that of FIG. 36;

FIG. 38 is a cross-sectional view of the semiconductor device during a manufacturing step following that of FIG. 37; and

FIG. 39 is a cross-sectional view of the semiconductor device during a manufacturing step following that of FIG. 38.

### DETAILED DESCRIPTION

Embodiments will hereinafter be described in detail based on drawings. In all the drawings for describing the embodiments, members having the same function will be identified by the same reference numerals and overlapping descriptions will be omitted. In the following embodiments, a description on the same or similar portion is not repeated in principle unless otherwise particularly necessary.

The symbol “−” and “+” means a relative concentration of an impurity having an n conductivity type or p conductivity type. For example, an impurity concentration of an n type impurity is high in this order: “n⁻” and “n⁺”.

### First Embodiment

The semiconductor devices of the present embodiment and the following embodiment are equipped with a nonvolatile memory (nonvolatile memory element, flash memory, or nonvolatile semiconductor memory device). In the present embodiment and the following embodiment, a description on the nonvolatile memory will be made using a memory cell having an n channel MISFET (metal insulator semiconductor field effect transistor) as a basic one.

The polarity (polarity of a voltage applied during write/erase/read operation or polarity of a carrier) in the present embodiment and the following embodiment is for describing the operation of a memory cell having an n channel MISFET as a basic one. When a memory cell has a p channel MISFET as a basic one, the same operation can be achieved in principle by reversing all the polarities of an applied potential, conductivity type of a carrier, and the like. In the present application, a description will be made while discriminating a semiconductor film from a silicide layer formed by a reaction between a metal film and a semiconductor film. In short, the term “silicide” as used herein means a compound between a metal and silicon and does not mean a semiconductor.

### Structure of Semiconductor Device of Present Embodiment

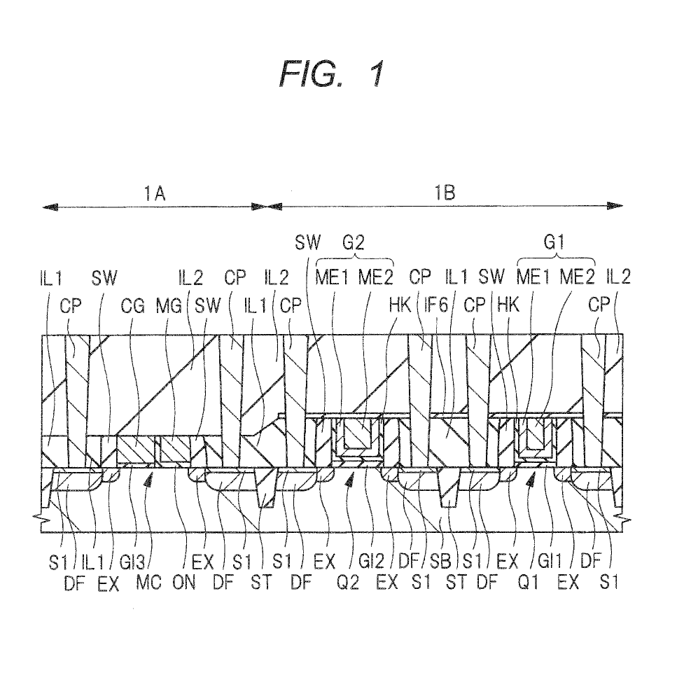

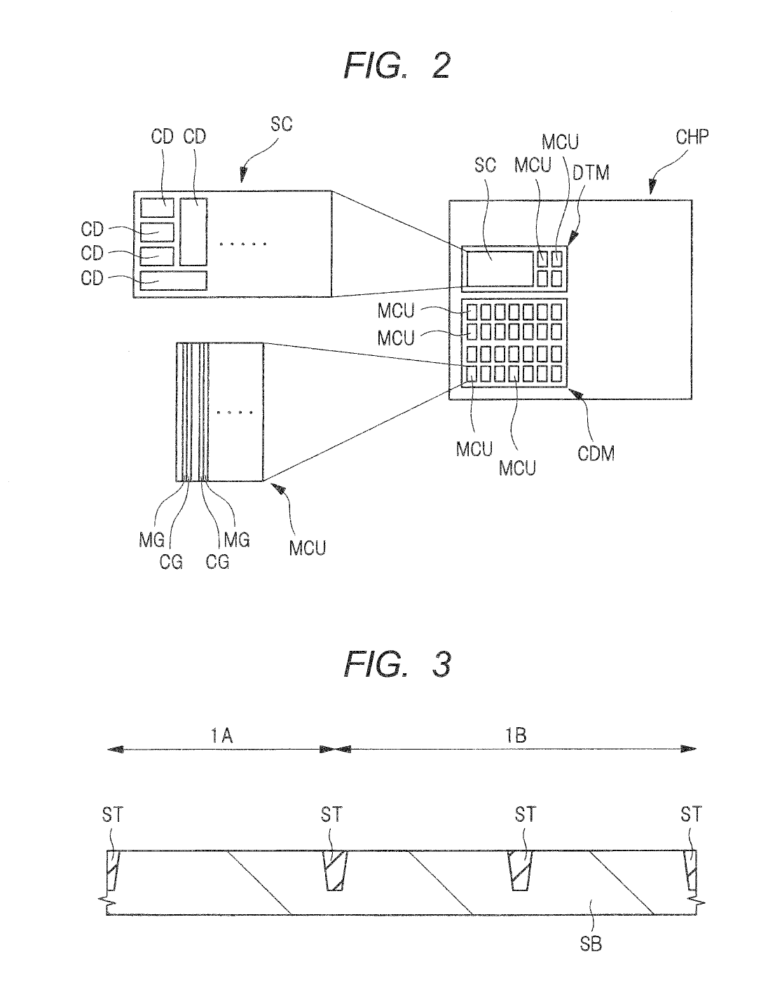

The semiconductor device of the present embodiment will be described referring to FIGS. 1 and 2. FIG. 1 is a cross-sectional view showing the semiconductor device of the present embodiment. FIG. 2 is a schematic plan view of a semiconductor chip including the semiconductor device of the present embodiment. FIG. 1 shows the cross-sectional view of a memory cell region 1A and a peripheral circuit region 1B in this order from the left side to the right side of the drawing. The memory cell region 1A and the peripheral circuit region 1B are arranged in a direction along the main surface on the same main surface side of a semiconductor substrate. FIG. 2 is an enlarged view of two positions on the upper surface of the semiconductor chip, that is, a power supply circuit portion and a memory array.

The term “peripheral circuit” as used herein means a circuit other than a nonvolatile memory. The peripheral circuit in a memory module is, for example, a control circuit, a sense amplifier, a column decoder, a row decoder, an input/output circuit from/to outside the module, or a power supply circuit, and that outside the memory module is a processor such as CPU, various analog circuits, SRAM (static random access memory) module, an input/output circuit from/to the outside, or the like. MISFETs formed in the peripheral circuit region 1B in FIG. 1 are a high breakdown voltage MISFET and a low breakdown voltage MISFET for peripheral circuit, respectively.

In the present embodiment, formation of n channel MISFETs (control transistor and memory transistor) in the memory cell region 1A will be described, but by inverting the conductivity type, p channel MISFETs (control transistor and memory transistor) can be formed in the memory cell region 1A. Similarly, in the present embodiment, formation of an n channel MISFET in the peripheral circuit region 1B will be described, but by inverting the conductivity type, a p channel MISFET can be formed in the peripheral circuit region 1B. Alternatively, both an n channel MISFET and a p channel MISFET, that is, a CMISFET (complementary MISFET) can be formed in the peripheral circuit region 1B.

As shown in FIG. 1, the semiconductor device of the present embodiment has a semiconductor substrate (semiconductor wafer) having, for example, a specific resistance of from about 1 to 10 Ωcm and made of p type single crystal silicon (Si). The semiconductor substrate SB has, in the main surface thereof, a plurality of trenches and the trenches each have therein an element isolation region ST that defines an active region and is made of an insulating film. The element isolation region ST is provided between the memory cell region 1A and the peripheral circuit region B arranged along the main surface of the semiconductor substrate SB for electrically isolating elements from each other. Also in the memory cell region 1A and the peripheral circuit region 1B, an element isolation region ST is provided for electrically isolating a plurality of elements from each other.

The element isolation region ST is made of an insulator such as silicon oxide and can be formed, for example, by STI (shallow trench isolation) or LOCOS (local oxidization of silicon). Here, the element isolation region ST is formed by STI.

A memory cell MC of a MONOS memory formed in the memory cell region 1A includes a control transistor and a memory transistor. The control transistor has a control gate electrode CG formed on the semiconductor substrate SB via a gate insulating film GI3 and a pair of source and drain regions formed in the upper surface of the semiconductor substrate SB at the side of the control gate electrode CG. The gate insulating film GI3 is made of, for example, a silicon oxide film.

The memory transistor has a memory gate electrode MG formed on the semiconductor substrate SB via an ONO film ON and a pair of source and drain regions formed in the upper surface of the semiconductor substrate SB at the side of the memory gate electrode MG. The control gate electrode CG and the memory gate electrode MG are adjacent to each other via the ONO film ON. The control transistor and the memory transistor share the same source and drain regions. Although not illustrated, the semiconductor substrate SB below the memory cell MC has, in the main surface thereof, a p well obtained by implantation of a p type impurity (for example, boron (B)) at a relatively low concentration.

This means that the main surface of the semiconductor substrate SB rightly below the control gate electrode CG and the memory gate electrode MG, that is, a channel region, has been implanted with a p type impurity. Such implantation of an impurity into the channel region is performed so as to raise the threshold voltage of the control transistor and the memory transistor. Excessive implantation of an impurity into the channel region however may enlarge an electric field generated between the channel region and each of the control gate electrode CG and the memory gate electrode MG and cause erroneous writing (disturb) in the memory cell MC.

The control transistor is a memory cell selection transistor so that it can be regarded as a select transistor. The control gate electrode can therefore be regarded as a select gate electrode. The memory transistor is a transistor for memory.

The pair of source and drain regions each have an LDD (lightly doped drain) structure, more specifically, a structure included of an n⁻ type semiconductor region EX which is an extension region implanted with an n type impurity (for example, As (arsenic) or P (phosphorus)) at a relatively low concentration and an n⁺ type semiconductor region DF which is a diffusion layer having an n type impurity concentration higher than that of the n⁻ type semiconductor region EX. In short, it has an LDD (lightly doped drain) structure. In each of the source and drain regions, the n⁻ type semiconductor region EX is placed at a position closer to the control gate electrode CG and the memory gate electrode MG than the n⁺ type semiconductor region DF. The n⁻ type semiconductor region EX has a depth smaller than that of the n⁺ type semiconductor region DF.

A sidewall SW made of an insulating film is contiguous to one of the side walls of a stacked film included of the gate insulating film GI3 and the control gate electrode CG and not adjacent to the memory gate electrode MG, and the other wide wall is covered with the ONO film ON. The sidewall SW is made of, for example, a stacked film of a silicon nitride film and a silicon oxide film. The stacked film and the sidewall SW may have therebetween an offset spacer included of a silicon nitride film, a silicon oxide film, or a stacked film of them.

A portion of the ONO film ON not contiguous to the stacked film including the control gate electrode CG, that is, the ONO film ON contiguous to the upper surface of the semiconductor substrate SB extends along the upper surface of the semiconductor substrate SB. Described specifically, the ONO film ON extending in a direction perpendicular to the main surface of the semiconductor substrate SB is contiguous to one of the side walls of the stacked film and the bottom portion of the ONO film ON extends along the upper surface of the semiconductor substrate SB at the side of the stacked film. This means that the ONO film ON has an L-shaped cross-sectional shape in the cross-section along the gate length direction of the control gate electrode CG and the memory gate electrode MG and a direction perpendicular to the main surface of the semiconductor substrate SB. In other words, the ONO film ON continuously extends from a region between the memory gate electrode MG and the control gate electrode CG to a region between the memory gate electrode MG and the semiconductor substrate SB.

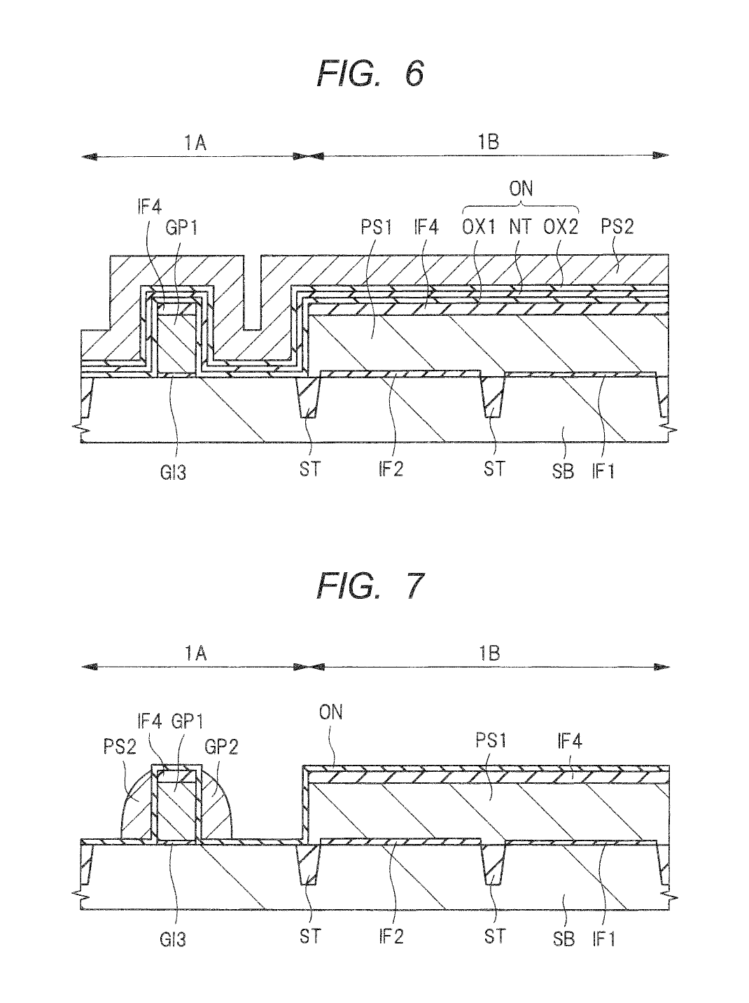

The ONO film ON is an insulating film for gate insulating film of the memory transistor and has therein a charge storage portion. Described specifically, the ONO film ON is included of a silicon oxide film OX1 (refer to FIG. 6) formed on the semiconductor substrate SB, a silicon nitride film NT (refer to FIG. 6) formed on the silicon oxide film OX1, and a silicon oxide film OX2 (refer to FIG. 6) formed on the silicon nitride film NT. To facilitate understanding of the drawings, in the cross-sectional views other than FIG. 6, the ONO film ON is shown as a single layer, but the actual ONO film ON has a stacked structure as described above. The memory gate electrode MG and the control gate electrode CG, and the memory gate electrode MG and the upper surface of the semiconductor substrate SB have each therebetween the ONO film ON. The silicon oxide film OX1, the silicon nitride film NT, and the silicon oxide film OX2 each has an L-shaped cross-sectional shape.

The sidewall SW is contiguous to one of the side walls of the stacked film included of the ONO film ON and the memory gate electrode MG and on the side opposite to the side of the control gate electrode CG. The stacked film and the sidewall SW may have therebetween an offset spacer. The upper surface of the n⁺ type semiconductor region DF constituting the source and drain regions is exposed from the sidewall SW.

A pair of n⁺ type semiconductor region DF has, on the upper surface thereof, a contact plug CP coupled thereto via a silicide layer S1. The contact plug CP is a coupling metal film that penetrates through an interlayer insulating film IL1 and an interlayer insulating film IL2 on the the interlayer insulating film IL1 which will be described later. The silicide layer S1 is made of, for example, a cobalt silicide layer, a nickel silicide layer, or a nickel platinum silicide layer.

The control gate electrode CG and the memory gate electrode MG are each made of a silicide layer. The silicide layer constituting the control gate electrode CG and the memory gate electrode MG is included of, for example, a cobalt silicide layer, a nickel silicide layer, or a nickel platinum silicide layer. The control gate electrode CG and the memory gate electrode MG are, from the upper surface to the lower surface thereof, silicided. This means that the control gate electrode CG and the memory gate electrode MG are fully-silicided gate electrodes, respectively.

Described specifically, the upper surface of the gate insulating film GI3 is contiguous to the silicide layer constituting the control gate electrode CG and the upper surface of the ONO film ON between the memory gate electrode MG and the semiconductor substrate SB is contiguous to the silicide layer constituting the memory gate electrode MG. This means that the upper surface of the gate insulating film GI3 is covered with the silicide layer constituting the control gate electrode CG; the upper surface of the ONO film ON between the memory gate electrode MG and the main surface of the semiconductor substrate SB is covered with the silicide layer constituting the memory gate electrode MG; and one of the side walls of the ONO film ON between the memory gate electrode MG and the control gate electrode CG is covered with the silicide layer constituting the memory gate electrode MG. In other words, there is no semiconductor layer made of silicon (Si) or the like between the control gate electrode CG and the gate insulating film GI3 and there is not semiconductor layer made of silicon (Si) or the like between the memory gate electrode MG and the ONO film ON.

The height of the upper surface of each of the control gate electrode CG and the memory gate electrode MG is, for example, 30 nm. The term “height” as used herein means a distance from the main surface of the semiconductor substrate SB to a specific position in a direction perpendicular to the main surface of the semiconductor substrate SB unless otherwise particularly specified.

Next, the peripheral circuit region 1B has therein a plurality of kinds of field effect transistors, that is, a high breakdown voltage MISFET Q2 and a low breakdown voltage MISFET Q1. The low breakdown voltage MISFET Q1 has a gate electrode G1 formed on the main surface of the semiconductor substrate SB via a gate insulating film GI1 and an insulating film HK in this order and a pair of source and drain regions formed in the main surface of the semiconductor substrate SB at the side of the gate electrode G1. The source and drain regions have, similar to the source and drain regions formed in the memory cell region 1A, an n⁻ type semiconductor region EX which is an extension region and an n⁺ type semiconductor region DF which is a diffusion region having an impurity concentration higher than that of the n⁻ type semiconductor region EX.

The gate insulating film GI1 has a film thickness of, for example, from 1 to 2 nm and is made of, for example, a silicon oxide film. The insulating film HK is an insulating film for gate insulating film and the gate electrode G1 is a metal gate electrode made of a metal film. More specifically, the insulating film HK covers therewith the bottom surface and side wall of the gate electrode G1. The insulating film HK is a so-called high-k film (high dielectric constant film), that is, an insulating material film having a dielectric constant (specific dielectric constant) higher than silicon oxide or silicon nitride. The term “high-k film” or “high dielectric constant film” as used herein means a film having a dielectric constant (specific dielectric constant) higher than that of silicon nitride.

As the insulating film HK, usable is a metal oxide film such as hafnium oxide film, zirconium oxide film, aluminum oxide film, tantalum oxide film, or lanthanum oxide film. These metal oxide films may contain one or both of nitrogen (N) and silicon (Si). The insulating film HK has a film thickness of, for example, 1.5 nm. Using a high dielectric constant film (here, the insulating film HK) as the gate insulating film is advantageous in reduction of a leakage current because the physical film thickness of the gate insulating film can be made larger compared with using a silicon oxide film.

The metal film constituting the gate electrode G1 is included of a stacked film of a metal film ME1 having a role of controlling the work function of the gate electrode G1 and a metal film ME2 formed on the metal film ME1 and having a role of reducing the resistance of the gate electrode G1. The metal film ME2 is covered, at the bottom surface and side wall thereof, with the metal film ME1. This means that the insulating film HK and the metal film ME2 have therebetween the metal film ME1.

Examples of a metal film usable as the metal film ME1 or ME2 include a titanium nitride (TiN) film, a tantalum nitride (TaN) film, a tungsten nitride (WN) film, a titanium carbide (TiC) film, a tantalum carbide (TaC) film, a tungsten carbide (WC) film, a tantalum carbonitride (TaCN) film, a titanium (Ti) film, a tantalum (Ta) film, a titanium aluminum (TiAl) film, and an aluminum (Al) film. The term “metal film” as used herein means a conductive film showing metal conductivity and it embraces not only a film made of a single metal (pure metal film) or alloy film but also a metal compound film showing metal conductivity. The metal film can be formed, for example, by sputtering.

For example, the metal film ME1 is included of a titanium nitride (TiN) film and the metal film ME2 is included of an aluminum (Al) film. At this time, the titanium nitride film is preferably thicker than the aluminum film. The aluminum film has relatively low resistance so that using it can contribute to reduction of the resistance of a control gate electrode CG, a memory gate electrode MG, and a gate electrode G1. The gate electrode G1 has a height of, for example, 50 nm. The side wall of the gate electrode G1 is covered with the sidewall SW. Although not illustrated, the semiconductor substrate SB has, in the main surface thereof below the low breakdown voltage MISFET Q1, a p well obtained by implantation of a p type impurity (for example, B (boron) at a relatively low concentration.

The high breakdown voltage MISFET Q2 has a structure resembling that of the low breakdown voltage MISFET Q1. Described specifically, the MISFET Q2 has a gate electrode G2 formed on the semiconductor substrate SB having therein the p well (not shown) via a gate insulating film GI2 and an insulating film HK and a pair of source and drain regions formed in the main surface of the semiconductor substrate SB at the side of the gate electrode G2.

The gate insulating film GI2 constituting the MISFET Q2 has a film thickness greater than that of the gate insulating film GI1. More specifically, the gate insulating film GI2 made of a silicon oxide film has a film thickness of, for example, from about 15 to 20 nm. The gate electrode G2 has a gate length greater than that of the gate electrode G1. Here, the gate length is a length of the gate electrode G2 in a direction orthogonal to the gate width direction, that is, the longitudinal direction of the gate electrode G2 extending in the depth direction of FIG. 1. In short, the gate length direction is a direction along which the source and drain regions sandwiching the gate electrode G2 therebetween face each other in plan view.

Thus, the gate electrode G2 has a large gate length and the gate insulating film GI2 has a large thickness because the MISFET Q2 is an element used for the purpose of supplying the memory cell MC with a high voltage and therefore, the MISFET Q2 needs to have an increased breakdown voltage. On the other hand, the low breakdown voltage MISFET Q1 is an element free from application of a high voltage and required to perform high-speed operation so that the gate electrode G1 has a small gate length and the gate insulating film GI1 has a relatively small film thickness.

Similar to the gate electrode G1, the gate electrode G2 is included of a stacked film of the metal films ME1 and ME2 and the gate electrode G2 has a height of, for example, 50 nm.

One of the characteristics of the semiconductor device of the present embodiment is that the control gate electrode CG and the memory gate electrode MG are each included of a silicide layer. The gate electrode of each of the MISFETs in the peripheral circuit region 1B is, on the other hand, a metal gate electrode. Another characteristic of the semiconductor device of the present embodiment is that the height of each of the control gate electrode CG and the memory gate electrode MG is lower than the height of each of the gate electrodes G1 and G2 of the MISFETs Q1 and Q2 in the peripheral circuit region 1B.

As shown in FIG. 1, an interlayer insulating film IL1 made of, for example, a silicon oxide film is buried in a region between the gate electrodes. The interlayer insulating film IL1 has a height different between the memory cell region 1A and the peripheral circuit region 1B. In the memory cell region 1A, the height of the upper surface of the interlayer insulating film IL1 is substantially similar to the height of the upper surface of each of the control gate electrode CG, the memory gate electrode MG, and the side wall SW adjacent to the gate electrodes thereof. In the peripheral circuit region 1B, the height of the upper surface of the interlayer insulating film IL1 is substantially similar to the height of the upper surface of each of the gate electrodes G1 and G2 and the sidewall SW adjacent to the side wall of the gate electrodes.

The height of the interlayer insulating film IL1 in the memory cell region 1A is, for example, 30 nm and the height of the interlayer insulating film IL1 in the peripheral circuit region 1B is, for example, 50 nm. Due to such a difference in height, the height of the upper surface of the interlayer insulating film IL1 changes in a region in the vicinity of the boundary between the memory cell region 1A and the peripheral circuit region 1B. The upper surface of the interlayer insulating film IL1 in the vicinity of the boundary slants to the main surface of the semiconductor substrate SB so that an adequate space must be secured. The gate electrodes G1 and G2 in the present embodiment are made of a metal film which has filled a trench opened in an insulating film including the interlayer insulating film IL1 and the sidewall SW. In short, the gate electrodes G1 and G2 are formed by a so-called gate last process.

An interlayer insulating film IL2 covers the upper surface of each of the interlayer insulating film IL1, the sidewall SW, the control gate electrode CG, the memory gate electrode MG, and the gate electrodes G1 and G2. The interlayer insulating film IL2 is made of, for example, a silicon oxide film and it has a planarized upper surface. A plurality of contact plugs CP penetrates through the interlayer insulating films IL1 and IL2. Some of the contact plugs CP are electrically coupled to an n⁺ type semiconductor region DF constituting each of the source and drain regions.

In an unillustrated region, the control gate electrode CG, the memory gate electrode MG, and the gate electrodes G1 and G2 each have an upper surface to which the contact plug CP has been coupled. Although not illustrated here, the interlayer insulating film IL2 has a plurality of wirings thereon. The contact plugs CP each have an upper surface coupled to the bottom portion of each the wirings. This means that a predetermined potential is supplied to each of the source and drain regions, the control gate electrode CG, the memory gate electrode MG, and the gate electrode G1 and G2 via the wirings (not illustrated) on the interlayer insulating film IL2 and the contact plugs CP. The wirings include a first wiring layer and the first wiring layer has thereover a second wiring layer, a third wiring layer, and the like successively. Thus, a stacked wiring layer included of these wiring layers is formed.

Next, the constitution of the semiconductor chip CHP shown in FIG. 2 will be described. The semiconductor chip CHP has a rectangular shape in plan view and a semiconductor substrate constituting the semiconductor chip CHP has thereon various semiconductor elements. The semiconductor chip CHP has, on the main surface thereof, a MONOS module DTM for data and a MONOS module CDM for code. The MONOS module DTM for data is a portion having a MONOS memory in which rewrite operation is performed frequently, while the MONOS module CTM for code is a region having a MONOS memory in which rewrite operation is scarcely performed. The semiconductor chip CHP shown in FIG. 2 has therein various modules as well as the MONOS modules CDM and DTM, but they are not shown here.

The MONOS modules DTM and CDM each have therein a plurality of memory arrays MCU. The MONOS module DTM however has therein a power supply circuit portion SC for rewriting. FIG. 2 includes a schematic plan view showing an enlarged memory array MCU. In the memory array MCU, the control gate electrode CG and the memory gate electrode MG adjacent to each other are arranged while extending in a predetermined direction (gate width direction). A plurality of memory cells having a pair of the control gate electrode CG and the memory gate electrode MG is arranged in a direction orthogonal to the gate width direction. With regard to the memory cells adjacent to each other, the control gate electrodes CG constituting them or the memory gate electrodes MG constituting them face each other.

The schematic plan view showing the enlarged memory array MCU includes only the control gate electrode CG and the memory gate electrode MG and omits the other members such as source and drain regions and contact plugs.

To the upper surface of each of the control gate electrode CG and the memory gate electrode MG extending in a predetermined direction in the memory array MCU, power supplying contact plugs (not shown) are coupled at predetermined intervals in the above direction. This means a plurality of power supply portions are provided at predetermined intervals for each of the control gate electrode CG and the memory gate electrode MG. In addition, an element isolation region extending in a direction orthogonal to the extending direction of the control gate electrode CG and the memory gate is placed (not shown) in the memory array MCU and the memory cells are isolated from each other.

FIG. 2 also shows a schematic plan view of an enlarged power supply circuit portion SC. The power supply circuit portion SC has therein a plurality of large-area capacitive elements CD for charge storage or planarization. The power supply circuit portion SC is used to generate a voltage necessary for write/erase of the MONOS memory.

A plurality of the memory cells MC each shown in FIG. 1 are arranged side by side in the memory array MCU shown in FIG. 2. The MISFETs Q1 and Q2 in the peripheral circuit region 1B shown in FIG. 1 are formed, for example in a region in the MONOS module CDM shown in FIG. 2 but other than the memory array MCU. The MISFETs Q1 and Q2 in the peripheral circuit region 1B shown in FIG. 1 are also formed, for example, in a region other than the memory array MCU in the MONOS module DTM and the power supply circuit portion SC shown in FIG. 2. The MISFETs Q1 and Q2, which are metal gate transistors, are provided in the MONOS modules CDM and DTM for signal control.

With regard to the MISFETs Q1 and Q2, for example, processors such as CPU, various analog circuits, SRAM memory module, and outside input/output circuit placed in a region of the semiconductor chip CHP other than the MONOS modules CDM and DTM are also included of the MISFETs Q1 and Q2 formed in the peripheral circuit region 1B.

Thus, the memory cell region 1A having therein a plurality of the memory cells collectively is discriminated clearly from the peripheral circuit region 1B having therein a plurality of the MISFETs Q1 and MISFETs Q2 collectively.

The gate electrode of the MISFETs in the peripheral circuit region 1B is included of a metal gate electrode formed by the gate last process.

### <Operation of Nonvolatile Memory>

Next, operation examples of the nonvolatile memory will be described referring to FIG. 19.

FIG. 19 is a table showing one example of voltage application conditions to each site of a select memory cell during “write”, “erase”, and “read” in the present embodiment. A voltage to be applied to each site of a memory cell as shown in FIG. 1 during “write”, “erase”, and “read” is listed in the table in FIG. 19. Described specifically, it includes a voltage Vmg to be applied to the memory gate electrode MG, a voltage Vs to be applied to the source region, a voltage Vcg to be applied to the control gate electrode CG, a voltage Vd to be applied to the drain region, and a base voltage Vb to be applied to the p well PW1. The term “select memory cell” as used herein means a memory cell selected as an object of “write”, “erase”, or “read” operation. In the example of the nonvolatile memory shown in FIG. 1, an active region on the right side of the memory gate electrode MG is a source region, while an active region on the left side of the control gate electrode CG is a drain region.

An example of preferred voltage application conditions is shown in the table of FIG. 19. The conditions are not limited to them, but can be changed variously if necessary. Further, in the present embodiment, injection of electrons and injection of holes into the silicon nitride film NT (refer to FIG. 6), which is a charge storage portion in the ONO film ON of the memory transistor, are defined as “write” and “erase”, respectively.

In the table of FIG. 19, the column A corresponds to an operation method using SSI for writing and BTBT for erasing; the column B corresponds to an operation method using SSI for writing and FN for erasing; the column C corresponds to an operation method using FN for writing and BTBT for erasing; and the column D corresponds to an operation method using FN for writing and FN for erasing.

The SSI method can be regarded as an operation method in which writing to memory cells is performed by injecting hot electrons into the silicon nitride film NT. The BTBT method can be regarded as an operation method in which erasing of memory cells is performed by injecting hot holes into the silicon nitride film NT. The FN method can be regarded as an operation method in which writing or erasing is performed by tunneling of electrons or holes. The FN method can also be expressed as follows. The FN write method can be regarded as an operation method in which writing to memory cells is performed by injecting electrons into the silicon nitride film NT by making use of a FN tunneling effect, and the FN erase method can be regarded as an operation method in which erasing of memory cells is performed by injecting holes into the silicon nitride film NT by making use of a FN tunneling effect. They will be described more specifically.

The write method includes a so-called SSI (source side injection) method, that is, a write method (hot electron injection write method) in which writing is performed by hot electron injection making use of source side injection and a so-called FN method, that is, a write method (tunneling write method) in which writing is performed by FN (Fowler Nordheim) tunneling.

In the SSI write method, writing is performed, for example, by applying voltages (Vmg=10 V, Vs=5 V, Vcg=1 V, Vd=0.5 V, Vb=0 V) as shown in “write operation voltage” in the column A or column B in the table of FIG. 19 to respective sites of the select memory cell that performs writing and thereby injecting electrons into the silicon nitride film NT in the ONO film ON of the select memory cell.

In this case, the hot electrons are generated in the channel region (between the source and the drain) below and between the two gate electrodes (memory gate electrode MG and control gate electrode CG) and the resulting hot electrons are injected into the silicon nitride film NT, which is a charge storage portion in the ONO film ON below the memory gate electrode MG. The injected hot electrons (electrons) are trapped in the trap level in the silicon nitride film NT in the ONO film ON. This leads to an increase in the threshold voltage of the memory transistor. This means that the memory transistor is brought to a write state.

In the FN write method, writing is performed, for example, by applying voltages (Vmg=−12 V, Vs=0 V, Vcg=0 V, Vd=0 V, Vb=0 V) as shown in “write operation voltage” in the column C or column D in the table of FIG. 19 to the respective sites of the select memory cell that performs writing and injecting electrons, which have been tunneled from the memory gate electrode MG, into the silicon nitride film NT in the ONO film ON. In this case, the electrons are injected into the ONO film ON, tunneling through the silicon oxide film OX2 (refer to FIG. 6) by FN tunneling (FN tunneling effect) from the memory gate electrode MG and trapped in the trap level in the silicon nitride film NT in the ONO film ON. This leads to an increase in the threshold voltage of the memory transistor. As a result, the memory transistor is brought to a write state.

In the FN write method, writing can also be performed by tunneling electrons from the semiconductor substrate SB and injecting them into the silicon nitride film NT in the ONO film ON. In this case, the write operation voltage is, for example, that obtained by inverting the polarity of “write operation voltage” in the column C or column D in the table of FIG. 19.

The erase method includes a so-called BTBT method, that is, an erase method in which erasing is performed by injecting hot holes by making use of BTBT (band-to-band tunneling: inter-band tunneling phenomenon) and a so-called FN method, that is, an erase method (tunneling erase method) in which erasing is performed by making use of FN (Fowler Nordheim) tunneling.

In the BTBT erase method, erasing is performed by injecting holes generated by BTBT into a charge storage portion (the silicon nitride film NT in the ONO film ON). For example, voltages (Vmg=−6 V, Vs=6 V, Vcg=0 V, Vd=open, Vb=0 V) as shown by “erase operation voltage” in the column A or column C in the table of FIG. 19 are applied to the respective sites of the select memory cell that performs erasing. Thus, holes are generated by the BTBT phenomenon, and by acceleration under an electric field, they are injected into the silicon nitride film NZ in the ONO film ON of the select memory cell. This leads to reduction in the threshold voltage of the memory transistor. As a result, the memory transistor is brought to an erase state.

In the FN erase method, erasing is performed by applying voltages (Vmg=12 V, Vs=0 V, Vcg=0 V, Vd=0 V, Vb=0 V) as shown by “erase operation voltage” in the column B or column D in the table of FIG. 19 to the respective sites of the select memory cell that performs erasing and injecting, in the silicon nitride film NT in the ONO film ON, holes which have been tunneled from the memory gate electrode MG in the select memory cell. In this case, the holes tunneled through the silicon oxide film OX2 (refer to FIG. 6) by FN tunneling (FN tunneling effect) from the memory gate electrode MG are injected into the ONO film ON and trapped in the trap level in the silicon nitride film NT in the ONO film ON. This results in reduction in the threshold voltage of the memory transistor. As a result, the memory transistor is brought to an erase state.

In the FN erase method, erasing can also be performed by tunneling the holes from the semiconductor substrate SB and injecting them into the silicon nitride film NT in the ONO film ON. In this case, the erase operation voltage is, for example, that obtained by inverting the polarity of the “erase operation voltage” in the column B or column D in the Table of FIG. 19.

During reading, for example, voltages as shown by “read operation voltage” in the column A, column B, column C, or column D in the table of FIG. 19 are applied to the respective sites of the select memory cell that performs reading. The write state and the erase state can be discriminated by defining the voltage Vmg applied to the memory gate electrode MG during reading to a value between the threshold voltage of the memory transistor in the write state and the threshold voltage in the erase state.

### Advantages of the Semiconductor Device of the Present Embodiment

Problems of a semiconductor device of Comparative Examples obtained by constituting the gate electrode of a memory cell from a semiconductor film will be described and the advantages of the semiconductor device of the present embodiment will be described.

Formation of a select gate electrode and a memory gate electrode constituting a memory cell from a semiconductor film such as silicon film and then, formation of a silicide layer thereon are considered as a method for forming a split gate MONOS memory. The gate electrode at least partially made of a semiconductor film may cause depletion at the bottom of the gate electrode at the time of inversion of a channel region of a transistor by application of a voltage to the gate electrode to turn it ON. This depletion becomes marked when the lower portion of the gate electrode is made of a semiconductor film, in other words, the semiconductor film constituting the gate electrode comes into contact with a gate insulating film rightly below the gate electrode. Such depletion in the gate electrode may cause a problem, that is, deterioration in drive capability of the transistor.

When the height of the upper surface of each of the control gate electrode and the memory gate electrode constituting the memory cell is large, distance between these gate electrodes and a wiring formed on an interlayer insulating film narrows, which may cause a problem, that is, an increase in the parasitic capacitance between the control gate electrode and the memory gate electrode, and the wiring.

In the semiconductor device of the present embodiment, on the other hand, the entirety of each the control gate electrode CG and the memory gate electrode MG constituting the memory cell MC is made of a silicide layer as shown in FIG. 1. This makes it possible to prevent deterioration of drive capability of the control transistor or memory transistor constituting the memory cell MC due to generation of a depletion layer in the gate electrode when a voltage is applied to the control gate electrode CG or the memory gate electrode MG at the time of driving the memory cell MC. As a result, the semiconductor device thus obtained has improved performance.

In the present embodiment, the height of the upper surface of each of the control gate electrode CG and the memory gate electrode MG constituting the memory cell MC is lower than the height of the upper surface of each of the gate electrodes G1 and G2 constituting the MISFETs Q1 and Q2 in the peripheral circuit region 1B. This leads to an increase in the distance between each of the control gate electrode CG and the memory gate electrode MG and a wiring (not shown) formed on the interlayer insulating film IL2. Parasitic capacitance between each of the control gate electrode CG and the memory gate electrode MG and a wiring can therefore be reduced. As a result, the semiconductor device thus obtained can have improved performance.

In addition, in the present embodiment, due to full silicidation of the control gate electrode CG and the memory gate electrode MG, the control gate electrode CG and the memory gate electrode MG can have significantly reduced resistance compared with a control gate electrode and a memory gate electrode included of a semiconductor film. The semiconductor device thus obtained can therefore be operated with saved power. Further, by reduction in the resistance of these electrodes, regions to which a contact plug is coupled in order to supply a potential to these gate electrodes, that is, power supply portions can be provided at an increased interval. An area of the memory array MCU can therefore be reduced. This facilitates miniaturization of the semiconductor chip CHP and as a result, a semiconductor device thus obtained can have improved performance.

In the present embodiment, the control gate electrode CG and the memory gate electrode MG have been fully silicided. Due to the mid gap work function of these gate electrodes, the threshold voltage of the select transistor increases by from about 0.3 to 0.4V. This contributes to reduction in an implantation amount of a p type impurity into the channel region and thereby relaxation of an electric field between the channel region and each of the control gate electrode CG and the memory gate electrode MG. Write disturbance can therefore be prevented. As a result, the semiconductor device thus obtained can have improved reliability.

Further in the present embodiment, the respective gate electrodes G1 and G2 of the MISFETs Q1 and Q2 are each included of a metal gate electrode. The gate electrodes G1 and G2 can therefore have a reduced size and have reduced resistance. As a result, the semiconductor device thus obtained can have improved performance.

### <Method of Manufacturing Semiconductor Device>

A method of manufacturing the semiconductor device of the present embodiment will be described referring to FIGS. 3 to 18.

FIGS. 3 to 18 are each a cross-sectional view of the semiconductor device of the present embodiment during manufacturing steps. FIGS. 3 to 18 are cross-sectional views in which a memory cell region 1A and a peripheral circuit region 1B are shown in this order from the left side to the right side of the drawings. They show how a memory cell of a nonvolatile memory in the memory cell region 1A and a high breakdown voltage MISFET and a low breakdown voltage MISFET in the peripheral circuit region 1B are formed.

Here, formation of n channel MISFETs (control transistor and memory transistor) in the memory cell region 1A will be described, but p channel MISFETs (control transistor and memory transistor) may be formed in the memory cell region 1A by inverting the conductivity type. Similarly, formation of an n channel MISFET in the peripheral circuit region 1B will be described here but a p channel MISFET may be formed in the peripheral circuit region 1B by inverting the conductivity type. Alternatively, both an n channel MISFET and a p channel MISFET, that is, a CMISFET may be formed in the peripheral circuit region 1B.

In manufacturing steps of a semiconductor device, first, as shown in FIG. 3, provided is a semiconductor substrate (semiconductor wafer) SB having a specific resistance of from about 1 to 10 Ωcm and made of p type single crystal silicon (Si). Then, an element isolation region ST that defines an active region is formed in the main surface of the semiconductor substrate SB.

The element isolation region ST is made of an insulator such as silicon oxide and can be formed, for example, by STI or LOCOS. Here, formation of the element isolation region by STI will be described.

Described specifically, a silicon oxide film and a silicon nitride film are successively stacked in order of mention on the semiconductor substrate SB. Then, by photolithography and dry etching, the silicon nitride film and the silicon oxide film are etched and a plurality of trenches is formed in the upper surface of the semiconductor substrate SB.

Next, these trenches are each filled with an insulating film made of, for example, silicon oxide and then the insulating films on the semiconductor substrate SB are removed by a polishing step or the like to form a plurality of element isolation regions ST. These element isolation regions ST are formed, for example, between the memory cell region 1A and the peripheral circuit region 1B and between MISFETs formed in the peripheral circuit region 1B. As a result, the structure as shown in FIG. 3 can be obtained.

Although not illustrated here, a p well is formed in the main surface of the semiconductor substrate SB in the memory cell region 1A and the peripheral circuit region 1B. The p well can be formed, for example, by ion implantation of a p type impurity such as boron (B) into the semiconductor substrate SB. The p wells in respective formation regions such as memory cell, high breakdown voltage MISFET, and low breakdown voltage MISFET formation regions can be formed by the same ion implantation step, but in order to provide elements having an optimized characteristic, the p wells can also be formed by respectively different ion implantation steps by carrying out individual patterning operations at the time of implantation.

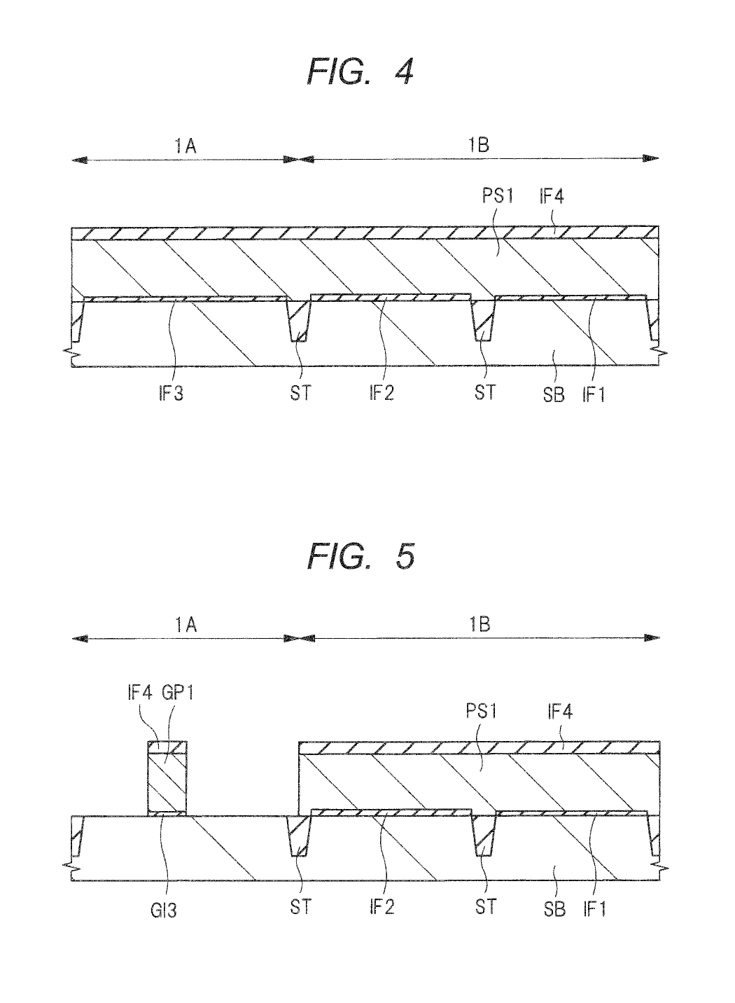

Next, as shown in FIG. 4, insulating films IF1 to IF3 for gate insulating film are formed on the main surface of the semiconductor substrate SB. Described specifically, the insulating film IF3 is formed on the upper surface of the semiconductor substrate SB in the memory cell region 1A and the insulating films IF1 and IF2 are formed on the upper surface of the semiconductor substrate 1B in the peripheral circuit region 1B. As the insulating films IF1 to IF3, for example, a silicon oxide film can be used. The insulating films IF1 and IF3 are formed by the same step. The insulating film IF2 has a film thickness greater than that of the insulating films IF1 and IF3.

In this step of forming the insulating films IF1 to IF3, first, an insulating film IF2 having a relatively large film thickness is formed on the upper surface of the semiconductor substrate SB by ISSG (in-situ steam generation) oxidation. Then, by using photolithography and etching, the insulating film IF2 is left in a high breakdown voltage MISFET formation region of the peripheral circuit region 1B while removing the insulating film IF2 from the other region. Next, insulating films IF3 and IF1 having a relatively small film thickness are formed on the semiconductor substrate SB in the memory cell region 1A and in a low breakdown voltage MISFET formation region of the peripheral circuit region 1B, respectively, by thermal oxidation or the like.

When the insulating film IF3 having a film thickness greater than that of the insulating IF1 is desired, at the time of leaving the above-mentioned insulating film IF2 while removing the insulating film IF2 from the other region, the insulating film IF2 in a formation region of the insulating film IF1 is left and then, the insulating film IF3 is formed. Then, after removal of the insulating film, that is, a stacked film of the insulating film IF2 and the insulating film IF3 from the formation region of the insulating film IF1, an insulating film IF1 thinner than the insulating film IF3 is formed. This makes it possible to form an insulating film IF3 having a film thickness greater than that of the insulating film IF1.

Then, a silicon film PS1 made of a polycrystalline silicon film is formed on the semiconductor substrate SB so as to cover the upper surface of the insulating films IF1 to IF3, for example, by CVD (chemical vapor deposition). After formation of the silicon film PS1 as an amorphous silicon film, heat treatment may be performed to covert the silicon film PS1 made of an amorphous silicon film into a silicon film PS1 made of a polycrystalline silicon film. The silicon film PS1 can also be provided as a low-resistance semiconductor film (doped polysilicon film) by ion implantation of an impurity at the time of or after film formation.

A dummy gate electrode which is to be formed in the peripheral circuit region 1B by using the silicon film PS1 and will be described later is removed by a step described later. Implantation of an impurity into the silicon film PS1 in the peripheral circuit region 1B for the purpose of reducing the resistance is not necessary, but implantation of, for example, an n type impurity is preferred from the standpoint of removing the silicon film PS1 by etching. The n type impurity to be introduced into the silicon film PS1 is preferably, for example, phosphorus (P).

Then, an insulating film IF4 is formed on the silicon film PS1, for example, by CVD. The insulating film IF4 is a cap insulating film made of, for example, silicon nitride (SiN). The insulating film IF4 may have a film thickness of, for example, from about 20 to 50 nm.

Next, as shown in FIG. 5, a stacked film of the insulating film IF4, the silicon film PS1, and the insulating film IF3 in the memory cell region 1A is patterned by photolithography and etching. As a result, the gate insulating film GI3 included of the insulating film IF3 is formed in the memory cell region 1A. Also by this etching step, a gate pattern GP1 included of the silicon film PS1 in the memory cell region 1A is formed. The gate pattern GP1 is a pattern which will be silicided by a later step into a control gate electrode. The gate pattern GP1 is a pattern extending in a predetermined direction in plan view. The term “predetermined direction” means a depth direction in FIG. 5.

The above-mentioned patterning step can be performed, for example, in the following manner. Described specifically, the insulating film IF4, the silicon film PS1, and the insulating film IF3 in the memory cell region 1A are processed by photolithography and dry etching into a gate pattern GP1 and a gate insulating film GI3. Alternatively, the insulating film IF4 in the memory cell region 1A may be processed using photolithography and etching, followed by processing of the silicon film PS1 and the insulating film IF3 with the resulting insulating film IF4 as a mask.

Next, as shown in FIG. 6, an ONO (oxide-nitride-oxide) film ON for gate insulating film of a memory transistor is formed on the entire main surface of the semiconductor substrate SB. The ONO film ON covers the upper surface of the semiconductor substrate SB and the side wall and upper surface of a stacked film included of the gate insulating films GI3 and IF4 and the gate pattern GP1 in the memory cell region 1A and covers the side wall and the upper surface of a film including the insulating films IF1, IF2, and IF4, and the silicon film PS1 in the peripheral circuit region 1B.

The ONO film ON is an insulating film having therein a charge storage portion. More specifically, the ONO film ON is included of a stacked film of a silicon oxide film OX1 formed on the semiconductor substrate SB, a silicon nitride film NT formed on the silicon oxide film OX1, and a silicon oxide film OX2 formed on the silicon nitride film NT.

The silicon oxide films OX1 and OX2 can be formed, for example, by oxidation treatment (thermal oxidation treatment) or CVD, or a combination of them. As the oxidation treatment at this time, ISSG oxidation may be used. The silicon nitride film NT can be formed, for example, by CVD.

In the present embodiment, the silicon nitride film NT is formed as an insulating film (charge storage layer) having a trap level. The film used as a charge storage layer is preferably a silicon nitride film from the standpoint of reliability, but it is not limited to a silicon nitride film. A high dielectric constant film (high dielectric constant insulating film) having a dielectric constant higher than that of a silicon nitride film, for example, aluminum oxide (alumina) film, hafnium oxide film, or tantalum oxide film can be used as a charge storage layer or a charge storage portion. It is to be noted that when the ONO film ON is formed, a structure such as the silicon film PS1 formed on the semiconductor substrate SB may be exposed to high temperatures.

The film thickness of the silicon oxide film OX1 can be set, for example, from about 2 to 10 nm; that of the silicon nitride film NT can be set, for example, at from about 5 to 15 nm; and that of the silicon oxide film OX2 can be set at, for example, from about 2 to 10 nm.

Next, a polycrystalline silicon film PS2 is formed on the entire main surface of the semiconductor substrate SB, for example, by CVD so as to cover the surface of the ONO film ON. The side wall and the upper surface of the ONO film ON exposed in the memory cell region 1A are therefore covered with the silicon film PS2. This means that the silicon film PS2 is formed on the side wall of the gate pattern GP1 via the ONO film ON. The silicon film PS2 has a film thickness of, for example, 40 nm. It can be obtained by forming the silicon film PS2 as an amorphous silicon film first and then heat treating the silicon film PS2 made of an amorphous silicon film into the silicon film PS2 made of a polycrystalline silicon film. The silicon film PS2 is, for example, a film implanted with a p type impurity (for example, boron (B)) at a relatively high concentration. The silicon film PS2 is a film provided for the formation of a gate pattern GP2 and a memory gate electrode MG which will be described later.

The term “film thickness” as used herein means, when it is a specific film, the thickness of the film in a direction perpendicular to the surface of a film underlying the specific film. For example, when the silicon film PS2 is formed on and along a plane extending along the main surface of the semiconductor substrate SB, like the upper surface of the ONO film ON, the film thickness of the silicon film PS2 means a thickness of the silicon film PS2 in a direction perpendicular to the main surface of the semiconductor substrate SB. In the case of a portion of the silicon film PS2 formed in contact with a wall perpendicular to the main surface of the semiconductor substrate SB, like the side wall of the ONO film ON, the film thickness means the thickness of the silicon film PS2 in a direction perpendicular to the side wall.

Next, as shown in FIG. 7, the upper surface of the ONO film ON is exposed by anisotropic etching to etch back (etch, dry etch, or anisotropically etch) the silicon film PS2. In this etch back step, the silicon film PS2 is anisotropically etched (etched back) to leave the silicon film PS2 in sidewall form on both side walls of the stacked film included of the gate insulating films GI3 and IF4, and the gate pattern GP1 via the ONO film ON.

As a result, a gate pattern GP2 included of the silicon film PS2 that has remained in sidewall form on one of the side walls of the stacked film via the ONO film ON is formed in the memory cell region 1A. The gate pattern GP2 formed on one of the side walls of the gate pattern GP1 is a semiconductor film which will be silicided in later step to be a memory gate electrode. By the above-mentioned etch back, the upper surface of the ONO film ON is exposed in the peripheral circuit region 1B.

Next, as shown in FIG. 8, a photoresist pattern (not shown) that covers the gate pattern GP2 adjacent to one of the side walls of the gate pattern GP1 and expose the silicon film PS2 adjacent to the other side wall of the gate pattern GP1 is formed on the semiconductor substrate SB by photolithography. Then, by etching with the photoresist pattern as an etching mask, the silicon film PS2 formed on the side opposite to the gate pattern GP2 with the gate pattern GP1 therebetween is removed. Then, the photoresist pattern is removed. At this time, the gate pattern GP2 covered with the photoresist pattern remains without being etched.

Next, a portion of the ONO film ON exposed without being covered with the gate pattern GP2 is removed by etching (for example, wet etching). At this time, in the memory cell region 1A, the ONO film ON rightly below the gate pattern GP2 remains without being removed. Similarly, the ONO film ON located between the stacked film of the gate insulating films GI3 and IF4 and the gate pattern GP1 and the gate pattern GP2 remains without being removed. The ONO film ON in the other region is removed so that the upper surface of the semiconductor substrate SB in the memory cell region 1A is exposed and the upper surface of the insulating film IF4 in the memory cell region 1A and the peripheral circuit region 1B is exposed. Also exposed is the side wall of the gate pattern GP1 not adjacent to the gate pattern GP2.

In such a manner, the gate pattern GP2 is formed on the semiconductor substrate SB so as to be adjacent to the gate pattern GP1 via the ONO film ON having therein a charge storage portion.

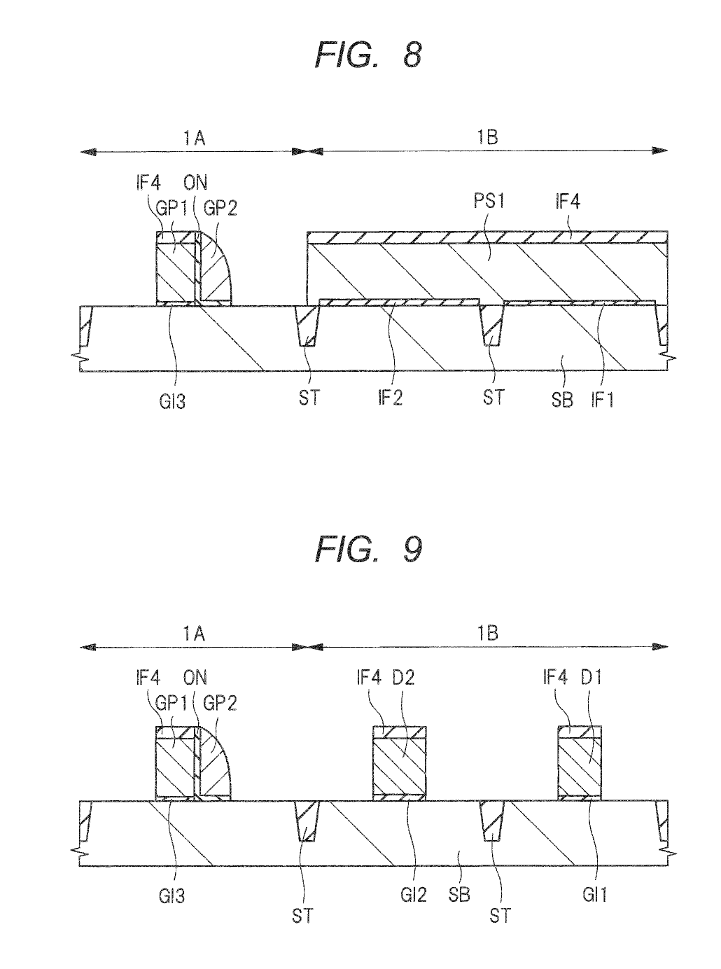

Next, as shown in FIG. 9, the insulating film IF4, the silicon film PS1, and the insulating films IF1 and IF2 in the peripheral circuit region 1B are patterned using photolithography and etching. In a high breakdown voltage MISFET formation region, a dummy gate electrode D2 included of the silicon film PS1 and a gate insulating film GI2 included of the insulating film IF2 are thereby formed. In a low breakdown voltage MISFET formation region, on the other hand, a dummy gate electrode D1 included of the silicon film PS1 and a gate insulating film GI1 included of the insulating film IF1 are formed. The dummy gate electrodes D1 and D2 are semiconductor films to be removed in a later step.

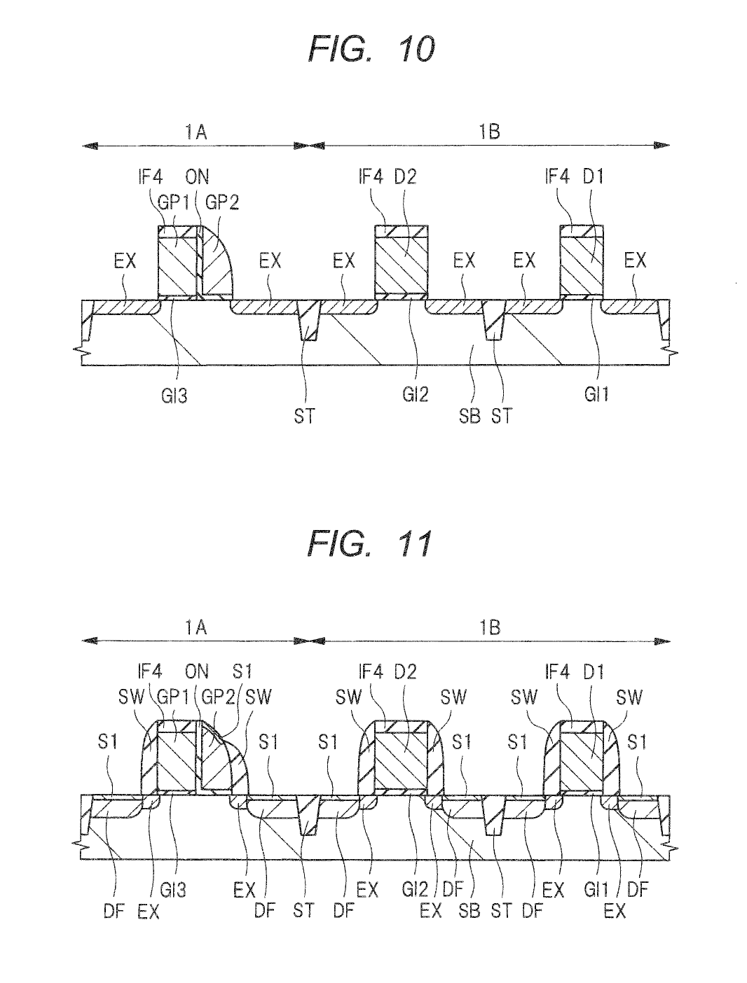

Next, as shown in FIG. 10, a plurality of n⁻ type semiconductor regions (impurity diffusion regions) EX is formed by ion implantation or the like. Described specifically, a plurality of n⁻ type semiconductor regions EX is formed, for example, by implanting an n type impurity such as arsenic (As) or phosphorus (P) into the semiconductor substrate SB by ion implantation while using the insulating film IF4, the gate pattern GP1, the gate pattern GP2, the dummy gate electrodes D1 and D2, and the ONO film ON as a mask. Before formation of the n⁻ type semiconductor region EX, an offset spacer that covers the side wall of a structure included of the gate patterns GP1 and GP2 and the side wall of each of the dummy gate electrodes D1 and D2 may be formed, for example, from a silicon nitride film or a silicon oxide film, or a stacked film thereof.

In the memory cell region 1A, the n⁻ type semiconductor regions EX formed in the upper surface of the semiconductor substrate SB at the side of the structure including the gate pattern GP1 and the gate pattern GP2 include a portion of source and drain regions of a control transistor and a memory transistor of the memory cell region 1A which will be formed later. In the peripheral circuit region 1B, the n⁻ type semiconductor regions EX formed in the upper surface of the semiconductor substrate SB at the side of each of the dummy gate electrode D1 and D2 include a portion of source and drain regions of each of MISFETs of the peripheral circuit region 1B which will be formed later. The n⁻ type semiconductor regions EX in the memory cell region 1A and those in the peripheral circuit region 1B can be formed by the same ion implantation step, but can also be formed by respectively different ion implantation steps.

Next, as shown in FIG. 11, a sidewall SW that covers both side walls of the structure including the gate pattern GP1, the gate pattern GP2, the gate insulating films GI3 and IF4, and the ONO film ON in the memory cell region 1A is formed. By this step, a sidewall SW that covers both side walls of each of the stacked film of the gate insulating film GI1, the insulating film IF4, and the dummy gate electrode D1 and the stacked film of the gate insulating film GI2, the insulating film IF4, and the dummy gate electrode D2 is formed in the peripheral circuit region 1B.

The sidewall SW can be formed in self alignment, for example, by successively forming a silicon oxide film and a silicon nitride film on the semiconductor substrate SB by CVD and then partially removing the silicon oxide film and the silicon nitride film by anisotropic etching to expose the upper surface of the semiconductor substrate SB and the upper surface of the insulating film IF4. This means that the sidewall SW may be formed from a stacked film, but an interface between films constituting the stacked film is not shown in this drawing. The stacked film having a sidewall width optimum for achieving element characteristics can be formed by an improved formation method of the stacked film, but a description on it is omitted here.

Next, an n⁺ type semiconductor region (impurity diffusion region) DF is formed in the memory cell region 1A and the peripheral circuit region 1B by ion implantation or the like. Described specifically, an n⁺ type semiconductor region can be formed by implanting an n type impurity (for example, arsenic (As) or phosphorus (P)) into the semiconductor substrate SB by ion implantation while using the insulating film IF4, the gate pattern GP1, the gate pattern GP2, the dummy gate electrodes D1 and D2, the ONO film ON, the sidewall SW, and the like as a mask (ion implantation preventive mask). The n⁺ type semiconductor region DF has an impurity concentration higher and a junction depth deeper than those of the n⁻ type semiconductor region EX.

As a result, source and drain regions included of the n⁻ type semiconductor region EX which is an extension region and the n⁺ type semiconductor region DF which is a diffusion layer and has an impurity concentration higher than that of the n⁻ type semiconductor region EX and having an LDD structure are formed.

In the memory cell region 1A, the n⁻ type semiconductor region EX and the n⁺ type semiconductor region DF formed in the upper surface of the semiconductor substrate SB at the side of the structure including the gate pattern GP1 and the gate pattern GP2 will include source and drain regions of a control transistor and a memory transistor which will be formed later in the memory cell formation region 1A. In the peripheral circuit region 1B, the n⁻ type semiconductor region EX and the n⁺ type semiconductor region DF formed in the upper surface of the semiconductor substrate SB at the side of each of the dummy gate electrodes D1 and D2 include source and drain regions of a low breakdown voltage MISFET which will be formed later in the peripheral circuit region 1B. The respective n⁺ type semiconductor regions DF of the memory cell region 1A and the peripheral circuit region 1B can be formed by the same ion implantation step, but can also be formed by respectively different ion implantation steps.

Next, heat treatment as activation annealing is performed to activate the impurity implanted into the semiconductor regions (n⁻ type semiconductor region EX and n⁺ type semiconductor region DF) for source and drain.

Next, a silicide layer S1 is formed. The silicide layer S1 can be formed by carrying out a so-called salicide (self aligned silicide) process. Described specifically, the silicide layer S1 can be formed in the following manner.

First, a metal film for the formation of the silicide layer S1 is formed (deposited) on the entire main surface of the semiconductor substrate SB including the upper surface of the n⁺ type semiconductor region DF and the upper surface of the gate pattern GP2. As the metal film, a film made of a single metal (pure metal film) or alloy film can be used. For example, the metal film is made of a cobalt (Co) film, a nickel (Ni) film, or a nickel platinum alloy film and it can be formed by sputtering or the like.

Then, heat treatment (heat treatment for the formation of the silicide layer S1) is given to the semiconductor substrate SB to cause reaction between the metal film and the surface layer portion of each of the n⁺ type semiconductor region DF and the gate pattern GP2. By this heat treatment, a silicide layer S1 is formed on the upper portion of each of the n⁺ type semiconductor region DF and the gate pattern GP2. Then, an unreacted portion of the metal film is removed by wet etching or the like to obtain the structure shown in FIG. 11.

The silicide layer S1 can be formed, for example, as a cobalt silicide layer, a nickel silicide layer, or a nickel platinum silicide layer. Since the upper surface of the gate pattern GP1 is covered with the insulating film IF4 serving as a cap film, the silicide layer S1 is not formed on the upper portion of the gate pattern GP1. Similarly, since the upper portion of each of the dummy gate electrodes D1 and D2 of the peripheral circuit region 1B is covered with a cap film, the silicide layer S1 is not formed on the upper portion of these electrodes. The upper portion of the gate pattern GP2 in sidewall form is exposed so that the silicide layer S1 is formed on this exposed portion. This silicide layer S1 is removed completely by a polishing step using CMP conducted in a later step.

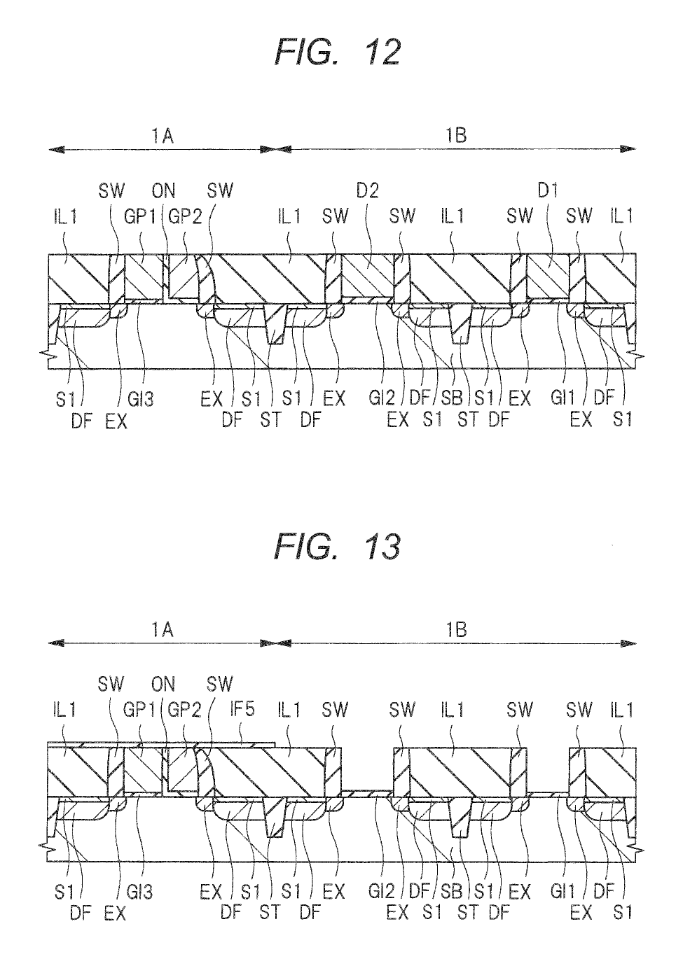

Next, as shown in FIG. 12, an interlayer insulating film IL1 is formed on the entire main surface of the semiconductor substrate SB so as to cover the gate pattern GP1, the gate pattern GP2, and the sidewall SW. The interlayer insulating film IL1 is made of a film composed of a silicon oxide film alone and can be formed using, for example, CVD. The interlayer insulating film IL1 is formed with a thickness greater than that of the gate pattern GP1.

Next, the upper surface of the interlayer insulating film IL1 is polished using CMP or the like. By this polishing, the upper surface of each of the gate pattern GP1, the gate pattern GP2, and the dummy gate electrodes D1 and D2 of the peripheral circuit region 1B is exposed. Described specifically, by this polishing step, the interlayer insulating film IL1 is polished until exposure of the upper surface of each of the gate pattern GP1, the gate pattern GP2, and the dummy gate electrodes D1 and D2. As a result, the insulating film IF4 is removed and also an upper portion of the sidewall SW is removed partially. The silicide layer S1 on the gate pattern GP2 is removed together with a portion of the upper portion of the gate pattern GP2 by this step.

Next, as shown in FIG. 13, after formation of an insulating film IF5 on the interlayer insulating film IL1, for example, by CVD, the insulating film IF5 is processed using photolithography and etching. The insulating film IF5 thereby remains in the memory cell region 1A. This means that the insulating film IF5 covers the upper surface of each of the gate patterns GP1 and GP2 and exposes the dummy gate electrodes D1 and D2. The insulating film IF5 is made of a silicon oxide film or a silicon nitride film.

Next, the dummy gate electrodes D1 and D2 are removed by etching. Here, the dummy gate electrodes D1 and D2 are removed by carrying out wet etching with, for example, an aqueous alkali solution while using the insulating film IF5 as a mask for protecting the gate patterns GP1 and GP2. As this aqueous alkali solution, for example, aqueous ammonia (NH₄OH) is used. Due to the removal of the dummy gate electrodes D1 and D2, a trench (recess or dent) is formed on each of the gate insulating films GI1 and GI2. The trench on the gate insulating film GI1 in the peripheral circuit region 1B is a region from which the dummy gate electrode D1 has been removed and the side wall on both sides of the trench is included of the sidewall SW. The trench on the gate insulating film GI2 in the peripheral circuit region 1B is a region from which the dummy gate electrode D2 has been removed and the side wall on both sides of the trench is included of the sidewall SW.

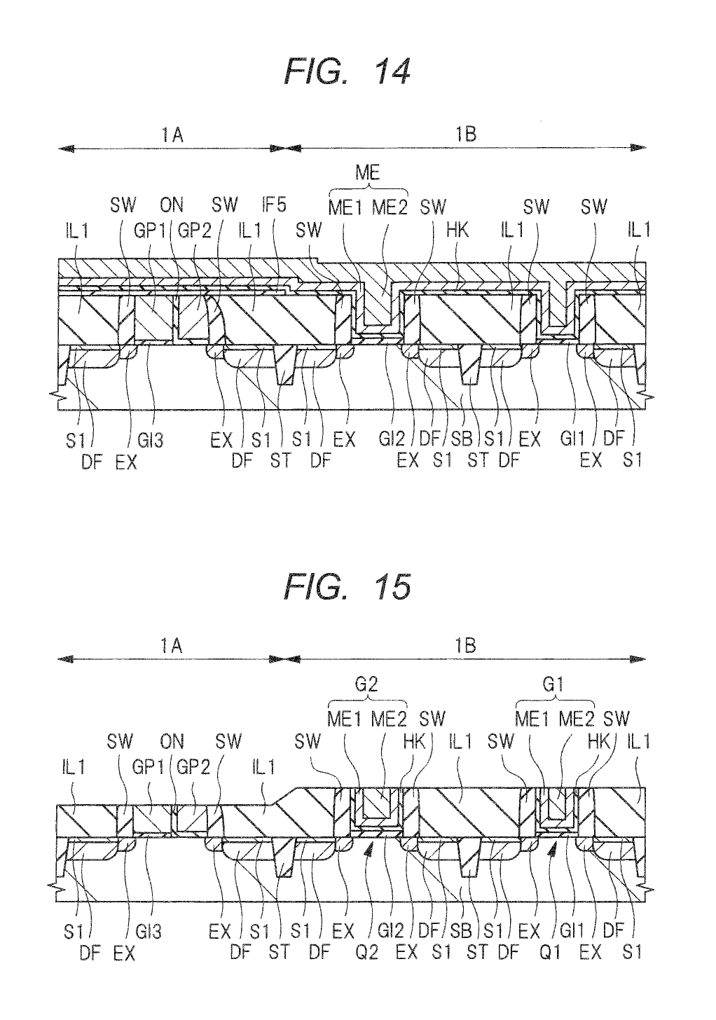

Next, as shown in FIG. 14, an insulating film HK is formed on the semiconductor substrate SB, that is, on the interlayer insulating film IL1 including the inner surface (bottom surface and side wall) of each of the trenches. Then, metal films ME1 and ME2 are formed successively on the semiconductor substrate SB, that is, on the insulating film HK, as a conductive film for gate electrode so as to completely fill each of the trenches.

In the step of forming the insulating film HK and the metal film ME1, each of the trenches is not filled completely. Each of the trenches is filled completely with the metal film ME2 formed on the metal film ME1. A metal film ME included of the metal films ME1 and ME2 is formed also on the interlayer insulating film ILL

The insulating film HK is an insulating film for gate insulating film and the metal film is a conductive film for gate electrode. More specifically, the insulating film HK is a film constituting a gate insulating film of a low breakdown voltage MISFET to be formed later in the peripheral circuit region 1B. The insulating film HK is a so-called high-k film (high dielectric constant film), that is, an insulating material film having a dielectric constant (specific dielectric constant) higher than that of each of silicon oxide and silicon nitride.

As the insulating film HK, a metal oxide film such as hafnium oxide film, zirconium oxide, aluminum oxide film, tantalum oxide film, or lanthanum oxide film can be used. These metal oxide films may further contain one or both of nitrogen (N) and silicon (Si). The insulating film HK can be formed for example by ALD (atomic layer deposition). The insulating film HK has a film thickness of, for example, 1.5 nm. The gate insulating film using a high dielectric constant film (here, the insulating film HK) can have an increased physical film thickness compared with that using a silicon oxide film so that it is advantageous in reduction in leakage current.

As the metal films ME1 and ME2, usable are metal films such as titanium nitride (TiN) film, tantalum nitride (TaN) film, tungsten nitride (WN) film, titanium carbide (TiC) film, tantalum carbide (TaC) film, tungsten carbide (WC) film, tantalum carbonitride (TaCN), titanium (Ti) film, tantalum film (Ta), titanium aluminum (TiAl) film, and aluminum (Al) film. The term “metal film” as used herein means a conductive film exhibiting metal conductivity. It is not only a film (pure metal film) made of a single metal or alloy film but also a metal compound film exhibiting metal conductivity. The metal film can be formed, for example, by sputtering.

Here, the metal film ME1 is formed from a titanium nitride (TiN) film and the metal film M2 on the titanium nitride film is formed from an aluminum (Al) film. The aluminum film is preferably thicker than the titanium nitride film. Since the aluminum film has low resistance, a gate electrode which will be formed later can have reduced resistance.

Next, as shown in FIG. 15, unnecessary portions of the metal film ME and the insulating film HK outside each of the trenches are removed by polishing by CMP or the like to fill each of the trenches with the insulating film HK and the metal films ME1 and ME2. At this time, also the insulating film IF5 is removed to expose the gate patterns GP1 and GP2. A gate electrode G1 is formed from the metal films ME1 and ME2 that have filled the trench on the gate insulating film GI1 in the peripheral circuit region 1B. A gate electrode G2 is formed from the metal films ME1 and ME2 that have filled the trench on the gate insulating film GI2 in the peripheral circuit region 1B.

As a result, a low breakdown voltage MISFET Q1 and a high breakdown voltage MISFET Q2 are formed in the peripheral circuit region 1B. The MISFET Q1 has the gate electrode G1 on the gate insulating film GI1 and the source and drain regions at the side thereof, while the MISFET Q2 has the gate electrode G2 on the gate insulating film GI2 and the source and drain regions at the side thereof.

The insulating film HK and the gate insulating film GI1 rightly below the gate electrode G1 include a gate insulating film of the MISFET Q1. The insulating film HK and the gate insulating film GI2 rightly below the gate electrode G2 include a gate insulating film of the MISFET Q2. The gate electrodes G1 and G2 are each a metal gate electrode. In the present embodiment, the dummy gate electrodes D1 and D2 are removed and replaced by the gate electrodes G1 and G2. The dummy gate electrodes D1 and D2 are pseudo gate electrodes and they can be regarded as gate electrodes for replacement.

In the present embodiment, the gate electrodes G1 and G2 are formed as a metal gate electrode by using a metal film. This makes it possible to suppress a depletion phenomenon of the gate electrodes G1 and G2 and eliminate parasitic capacitance. In addition to this advantage, the transistor element can be downsized (the gate insulating film can be thinned).

In the peripheral circuit region 1B, the gate electrode G1 is, at the bottom surface and side wall thereof, adjacent to the insulating film HK on the gate insulating film GI1. This means that the gate electrode G1 and the semiconductor substrate SB have therebetween the gate insulating film GI1 and the insulating film HK and the gate electrode G1 and the sidewall SW have therebetween at least the insulating film HK. Similarly, the gate electrode G2 is, at the bottom surface and side wall thereof, adjacent to the insulating film HK on the gate insulating film GI2. This means that the gate electrode G2 and the semiconductor substrate SB have therebetween the gate insulating film GI2 and the insulating film HK and the gate electrode G2 and the sidewall SW have therebetween at least the insulating film HK.

When as described above, the polishing step is performed using CMP or the like in order to remove an unnecessary portion of the metal film ME on the interlayer insulating film IL1, the height of each of the interlayer insulating film IL1, the sidewall SW, and the gate patterns GP1 and GP2 in the memory cell region 1A becomes lower than the height of each of the interlayer insulating film IL1, the sidewall SW, and the gate electrodes G1 and G2 in the peripheral circuit region 1B. In short, a height difference appears in the members to be polished between the memory cell region 1A and the peripheral circuit region 1B.

For example, when the height of each of the interlayer insulating film IL1, the sidewall SW, and the gate electrodes G1 and G2 in the peripheral circuit region 1B is 50 nm after the polishing step, the height of the structure on the semiconductor substrate SB in the memory cell region 1A becomes lower by from about 10 to 20 nm than the height of the structure of the peripheral circuit region 1B. In this case, for example, the height of each of the interlayer insulating film IL1, the sidewall SW, and the gate patterns GP1 and GP2 in the memory cell region 1A becomes 30 nm.

Such a difference occurs because during the polishing step until the polishing is completed after removal of the metal film ME on the interlayer insulating film IL1, the gate patterns GP1 and GP2 in the memory cell region 1A in which a polishing rate is higher than that in the peripheral circuit region 1B are etched more than the gate electrodes G1 and G2 in the peripheral circuit region 1B. Such a difference in polishing rate occurs because the peripheral circuit region 1B has therein many gate electrodes G1 and G2 which are metal gate electrodes resistant to polishing, while the memory cell region 1A has therein no metal gate electrode and has many gate patterns GP1 and GP2 made of a silicon film which are easily polished.

The peripheral circuit region 1B has therein metal films as a gate electrode at a high density, while the memory cell region 1A has therein no metal gate electrode so that in the polishing step, films in the memory cell region 1A are polished faster than films in the peripheral circuit region 1B. In the present embodiment, the gate patterns GP1 and GP2 have thus a lower height by making use of a difference in polishing rate which occurs due to the material of the gate electrodes or density thereof.

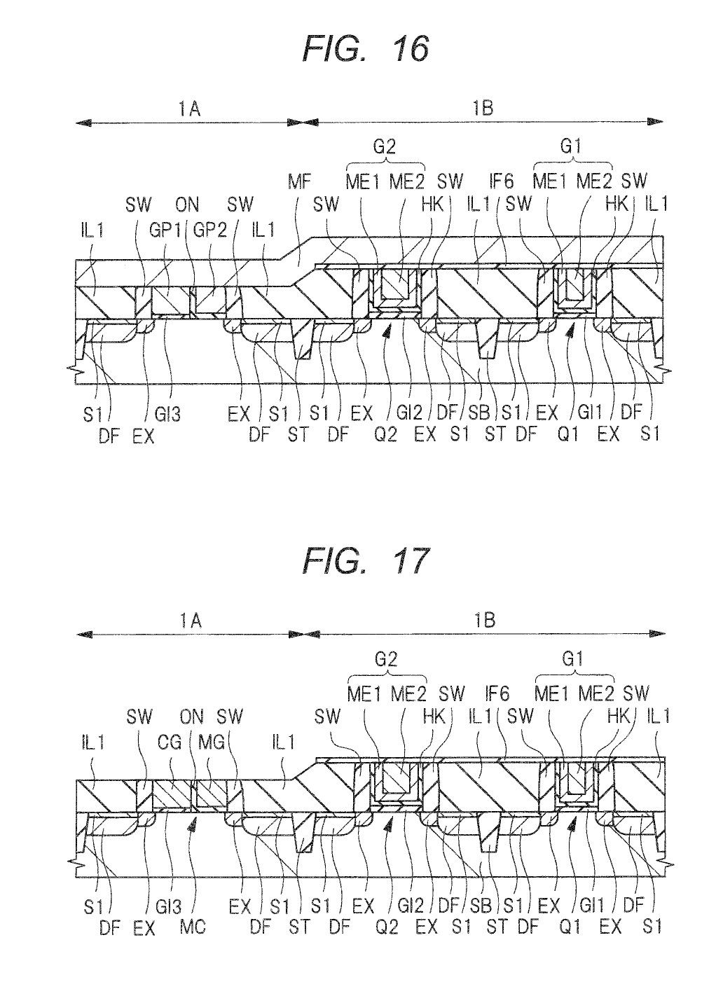

Next, as shown in FIG. 16, a pattern of an insulating film IF6 covering the peripheral circuit region 1B is formed using photolithography and etching. The insulating film IF6 is an insulating film that exposes the upper surface of the gate patterns GP1 and GP2 in the memory cell region 1A and covers the gate electrodes G1 and G2. It is made of, for example, a silicon oxide film. Then, a metal film MF for the salicide process is formed on the entire main surface of the semiconductor substrate SB, for example, by sputtering. As the metal film, a film included of a single metal (pure metal film) or an alloy film can be used. For example, it is included of a cobalt (Co) film, a nickel (Ni) film, or a nickel platinum alloy film. It can be formed by sputtering or the like.

The metal film MF is contiguous to the insulating film IF6 and the gate patterns GP1 and GP2 and not contiguous to the gate electrodes G1 and G2. The metal film MF needs a thickness enough for converting all the silicon films constituting the gate patterns GP1 and GP2 lying therebelow into silicide.

After formation of the insulating film IF6 but before formation of the metal film MF, a step of etching back the upper surface of the gate patterns GP1 and GP2 may be provided. By providing such an etch back step to decrease the height of the upper surface of each of the gate patterns GP1 and GP2, a control gate electrode and a memory gate electrode to be formed later by silicidation of the gate patterns GP1 and GP2 can be prevented from causing a leakage or short-circuit through a route on the ONO film ON. Further, by providing such an etch back step to decrease the height of the upper surface of each of the gate patterns GP1 and GP2, hot treatment time to be performed later for the silicidation of the gate patterns GP1 and GP2 can be shortened. This can prevent the insulating film HK in the peripheral circuit region 1B from being damaged by the heat treatment.

Next, as shown in FIG. 17, the semiconductor substrate SB is heat treated (heat treated for the formation of a silicide layer S1) to react the gate patterns GP1 and GP2 with the metal film MF. By this reaction, a control gate electrode CG is obtained by full silicidation of the gate pattern GP1 and a memory gate electrode MG is obtained by full silicidation of the gate pattern GP2. The control gate electrode CG and the memory gate electrode MG each made of the silicide layer is, for example, included of a cobalt silicide layer, a nickel silicide layer, or a nickel platinum silicide layer.

Then, an unreacted portion of the metal film MF is removed by wet etching or the like. In this wet etching step, an unnecessary portion of the metal film which has not reacted with the semiconductor film constituting the gate patterns GP1 and GP2 is removed using a chemical solution. The gate electrodes G1 and G2 made of a metal film are covered with the insulating film IF6 and are not exposed to the chemical solution so that they are not removed.

The gate patterns GP1 and GP2 can be silicided while preventing removal of the gate electrodes G1 and G2. The control gate electrode CG and the memory gate electrode MG are, from the top surface to the bottom surface, included of a silicide layer and do not contain a semiconductor layer. Further, the control gate electrode CG and the gate insulating film GI3, and the memory gate electrode MG and the ONO film ON have no semiconductor film therebetween. This means that the gate insulating film GI3 is contiguous to the silicide layer constituting the control gate electrode CG and the ONO film ON is, at the upper surface thereof, contiguous to the silicide layer constituting the memory gate electrode MG.

By the above-mentioned steps, a memory cell MC including the control gate electrode CG, the memory gate electrode MG, and the source and drain regions formed in the main surface of the semiconductor substrate SB at the side of these electrodes are formed. This means that in the memory cell region 1A, the control gate electrode CG and a pair of the source and drain regions formed in the upper surface of the semiconductor substrate SB at the side of the control gate electrode CG include a control transistor. The gate insulating film GI3 rightly below the control gate electrode CG includes the gate insulating film of the control transistor. In the memory cell region 1A, the memory gate electrode MG and a pair of the source and drain regions formed in the upper surface of the semiconductor substrate at the side of the memory gate electrode MG include a memory transistor. The ONO film ON below the memory gate electrode MG includes the gate insulating film of the memory transistor.

Thus, the control transistor and the memory transistor share a pair of source and drain regions and these control transistor and memory transistor include the memory cell MC.

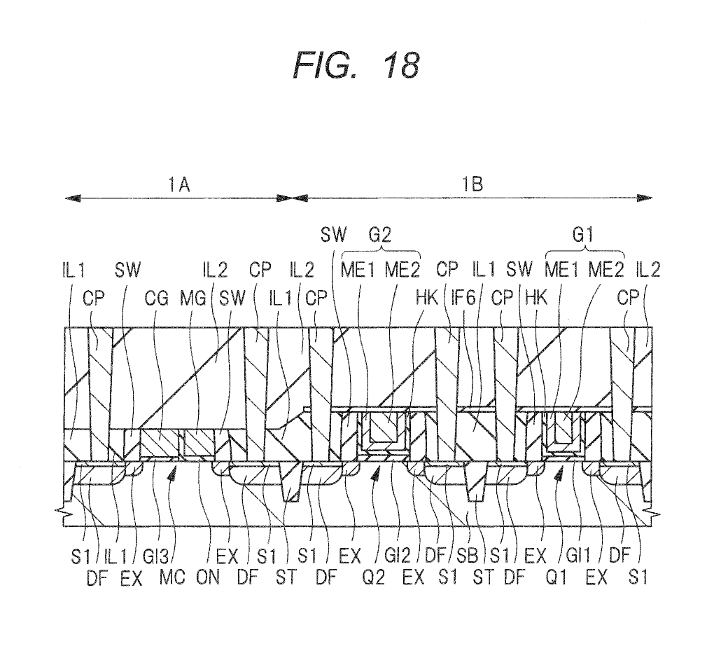

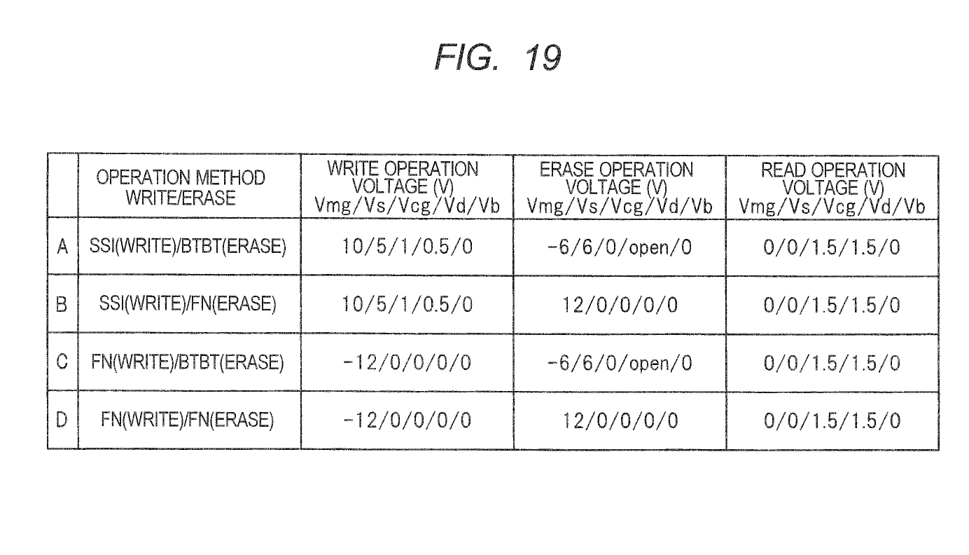

Next, as shown in FIG. 18, an interlayer insulating film and a plurality of contact plugs are formed. Described specifically, first, an interlayer insulating film IL2 covering the entire upper surface of the semiconductor substrate SB including the memory cell region 1A and the peripheral circuit region 1B is formed, for example, by CVD. The interlayer insulating film IL2 is included of, for example, a silicon oxide film and covers the upper surface of each of the control gate electrode CG, the memory gate electrode MG, the gate electrodes G1 and G2, and the interlayer insulating film ILL

Next, the interlayer insulating films IL1, IL2, and IF6 are dry etched using a photoresist pattern (not shown) formed on the interlayer insulating film IL2 as an etching mask by photolithography. By this dry etching, a plurality of contact holes (opening portions or through-holes) penetrating through the interlayer insulating films IL1 and IL2 and a plurality of contact holes penetrating through the interlayer insulating films IL1, IL2, and IF6 are formed.

Next, a plurality of conductive contact plugs CP made of tungsten (W) or the like is formed as a coupling conductor in each of the contact holes. The contact plugs CP are formed, for example, by forming a barrier conductor film (for example, a titanium film or a titanium nitride film, or a stacked film thereof) on the interlayer insulating film IL2 including the inside of the contact hole. Then, after formation of a main conductor film included of a tungsten film or the like on the barrier conductor film to completely fill each of the contact holes therewith, an unnecessary portion of the main conductor film and the barrier conductor film outside the contact hole is removed by CMP, etch back, or the like to form a contact plug CP. To simplify the drawing, the barrier conductor film and the main conductor film (tungsten film) constituting the contact plug CP are shown as one body in FIG. 18.

The contact plug CP buried in the contact hole is coupled to the upper portion of each of the n⁺ type semiconductor region DF, the control gate electrode CG, the memory gate electrode MG, and the gate electrodes G1 and G2. From the bottom portion of each of the contact holes, a portion of the main surface of the semiconductor substrate SB, for example, a portion of the silicide layer S1 on the surface of the n⁺ type semiconductor region DF, a portion of the control gate electrode CG, a portion of the memory gate electrode MG, a portion of the gate electrode G1, a portion of the gate electrode G2, and the like are exposed. The cross-sectional view of FIG. 18 shows that a portion of the silicide layer S1 on the surface of the n⁺ type semiconductor region DF is exposed from the bottom portion of a plurality of the contact holes and the contact plugs CP that fill the contact holes, respectively, are electrically coupled to the n⁺ type semiconductor region DF.

To each of the control gate electrode CG and the memory gate electrode MG extending in the gate width direction, the contact plugs CP are coupled at predetermined intervals in an unillustrated region. This means that for each of the control gate electrode CG and the memory gate electrode MG, two or more power supply portions are provided at predetermined intervals.

Although steps thereafter are omitted from the drawing, a first wiring layer including a first layer wiring is formed on the interlayer insulating film IL2 in which the contact plug CP has been buried. This wiring can be formed using the damascene technology. The first wiring layer has an interlayer insulating film and a first-layer wiring penetrating therethrough. A plurality of first-layer wirings is coupled to the upper surface of each of the contact plugs CP shown in FIG. 18. Then, a second wiring layer, a third wiring layer, and the like are formed successively on the first wiring layer to form a stacked wiring layer. Then, the semiconductor wafer is diced by a dicing step into a plurality of semiconductor chips.

The semiconductor device of the present embodiment is formed as described above. Here, the description has been made using, as an example, a so-called high-k last manufacturing method, that is, a method of forming the insulating film HK after removal of the dummy gate electrode. A so-called high-k first manufacturing method, that is, a method of forming the insulating film HK before removal of the dummy gate electrode may be used instead.

### Advantage of the Method of Manufacturing the Semiconductor Device of the Present Embodiment

Next, described are problems of a method of manufacturing a semiconductor device of Comparative Example including constituting a gate electrode of a memory cell from a semiconductor film and constituting a gate electrode in a peripheral circuit region from a metal film formed by a gate last process, followed by description on the advantages of the method of manufacturing the semiconductor device of the present embodiment.

For the formation of a split gate type MONOS memory, it is possible to include a select gate electrode and a memory gate electrode, which include a memory cell, from a semiconductor film such as a silicon film and then form a silicide layer on the semiconductor film. When at least a portion of the gate electrode is included of a semiconductor film, application of a voltage to the gate electrode to turn on the gate electrode, depletion occurs at the bottom in the gate electrode at the time of inversion of a channel region of a transistor. Such depletion in the gate electrode causes deterioration in drive capability of the transistor.

In order to form some of the gate electrodes on the semiconductor substrate by the gate last process, dummy gate electrodes are formed on the semiconductor substrate and then, a space between the dummy gate electrodes is filled with an interlayer insulating film. The upper surface of the interlayer insulating film is thereafter polished to expose the upper surface of the dummy gate electrodes. After removal of the dummy gate electrodes to form a trench, the trench is filled with, for example, a metal gate electrode. Here, the following problem occurs when the control gate electrode and the memory gate electrode constituting the memory cell is included of a semiconductor film and the gate electrode of the MISFET in the peripheral circuit region is included of a metal film formed by the gate last process.

When the above-mentioned polishing is performed, polishing characteristics differ between the memory cell region having therein the control gate electrode and the memory gate electrode each included of a semiconductor film and the peripheral circuit region having therein the metal gate electrode. The height of the control electrode and the metal gate electrode therefore becomes lower than that of the metal gate electrode. At this time, variations in the height occur among the control gate electrodes and variations in the height occur among the memory gate electrodes.

When after the polishing, a silicide layer is formed to cover the upper surface of each of the control gate electrode and the memory gate electrode, variations in the thickness of a semiconductor film lying below the silicide layer occur due to variations in the height of the control gate electrode CG and the memory gate electrode MG. This may cause variations in characteristics among the memory cells. In particular, significant variations in work function occur due to a difference in the material of the gate electrode contiguous to the gate insulating film, depending on whether the semiconductor film remains or does not remain in the gate electrode.

On the other hand, in the method of manufacturing the semiconductor device of the present embodiment, as shown in FIG. 17, the control gate electrode CG and the memory gate electrode MG constituting the memory cell MC are each included of only a silicide layer. This makes it possible to prevent deterioration in the drive capability of the control transistor or memory transistor constituting the memory cell MC which is caused by generation of a depletion layer in the gate electrode by application of a voltage to the control gate electrode CG or the memory gate electrode MG at the time of driving the memory cell MC. As a result, the semiconductor device thus obtained can have improved performance.

In the present embodiment, due to the difference in polishing rate described above referring to FIG. 16, the height of each of the gate patterns GP1 and GP2 becomes lower than the height of each of the gate electrodes G1 and G2 in the peripheral circuit region 1B. Therefore, the height of the upper surface of each of the control gate electrode CG and the memory gate electrode MG constituting the memory cell MC shown in FIG. 18 is lower than the height of the upper surface of each of the gate electrodes G1 and G2 constituting the MISFETs Q1 and Q2 in the peripheral circuit region 1B. A distance between each of the control gate electrode CG and the memory gate electrode MG and a wiring (not shown) formed on the interlayer insulating film IL2 can therefore be enlarged. This leads to reduction in parasitic capacitance between each of the control gate electrode CG and the memory gate electrode MG and a wiring. As a result, the semiconductor device thus obtained can have improved performance.

In the present embodiment, since the control gate electrode CG and the memory gate electrode MG have been fully silicided, the control gate electrode CG and the memory gate electrode MG each have significantly reduced resistance compared with those each included of a semiconductor film. The semiconductor device thus obtained can save power. Further, since these electrodes have reduced resistance, regions to which a contact plug is coupled to supply a potential to these gate electrodes, that is, power supply portions can be provided at increased intervals. This leads to a decrease in the area of the memory array MCU. This facilitates miniaturization of the semiconductor chip so that the semiconductor device thus obtained can have improved performance.

In the present embodiment, the control gate electrode CG and the memory gate electrode MG are fully silicided ones. Due to the mid gap work function of these gate electrodes, the threshold voltage of the select transistor increases by from about 0.3 to 0.4V. This contributes to reduction in an implantation amount of a p type impurity into a channel region and thereby relaxation of an electric field between the channel region and each of the control gate electrode CG and the memory gate electrode MG. Write disturbance can therefore be prevented. As a result, the semiconductor device thus obtained can have improved reliability.

In the present embodiment, even when variations occur in height among the control gate electrodes CG and among the memory gate electrodes MG shown in FIG. 18 due to the polishing step described referring to FIG. 15, variations in characteristics among memory cells can be prevented.

Described specifically, variations in the height among the control gate electrodes CG and among the memory gate electrodes MG due to the above-mentioned polishing step lead to variations in the film thickness among the silicide layers formed over the control gate electrodes CG and the memory gate electrodes MG. Since the film thickness of the respective silicide layers contiguous to the upper portion of the gate electrodes differs among the gate electrodes, there occurs a difference in change of work function of the gate electrodes. Therefore, variations in characteristics may occur among the memory cells.

In the present embodiment, however, since the control gate electrode CG and the memory gate electrode MG have been fully silicided, no difference occurs in the volume of the semiconductor film in the gate electrode among the gate electrodes in the memory cell region 1A. Therefore, occurrence of variation in the characteristics can be prevented.

Further, in the present embodiment, based on a difference in polishing rate in the polishing step described referring to FIG. 15, the height of each of the control gate electrodes CG and the memory gate electrodes MG shown in FIG. 18 is made lower than the height of the gate electrodes G1 and G2. In short, the gate patterns GP1 and GP2 shown in FIG. 15 have a reduced film thickness. This makes it possible to decrease the time required for heat treatment for full silicidation described referring to FIG. 17 and therefore the insulating film HK, which is a high-k film, in the peripheral circuit region 1B can be prevented from being damaged by the heat treatment. As a result, the semiconductor device thus obtained can have improved reliability.

In the present embodiment, the gate electrodes G1 and G2 of the MISFETs Q1 and Q2 are each included of a metal gate electrode. The gate electrodes G1 and G2 can therefore have a reduced size and reduced resistance. As a result, the semiconductor device thus obtained can have improved performance.

### First Modification Example

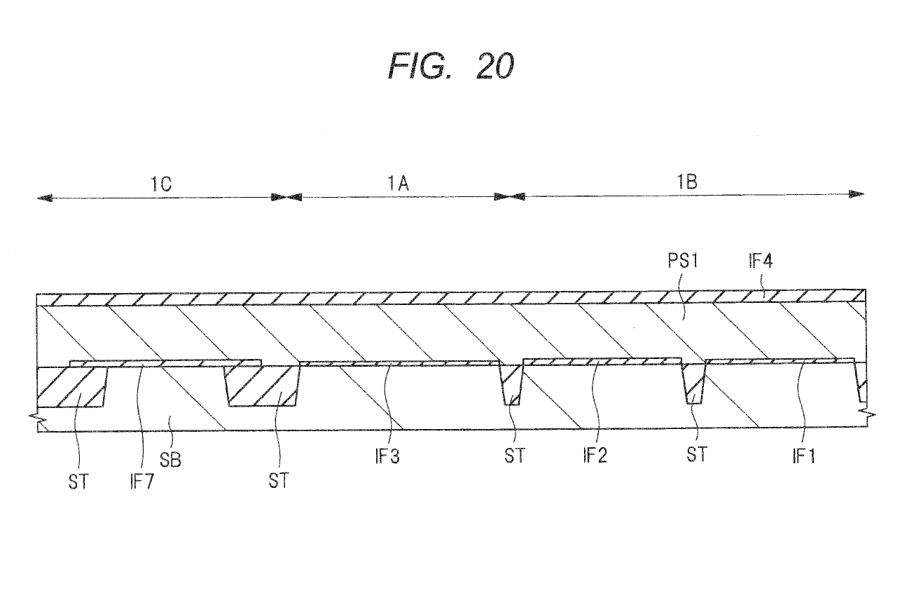

Next, manufacturing steps of a first modification example of the semiconductor device of the present embodiment will be described referring to FIGS. 20 to 26. FIGS. 20 to 26 are cross-sectional views of the first modification example of the semiconductor device of the present embodiment during manufacturing steps. FIGS. 20 to 26 show a memory cell region 1A and a peripheral circuit region 1B as in FIGS. 3 to 18 and they further include, on the left side thereof, a capacitive element region 1C. This means that in the present modification example, steps for forming a capacitive element while carrying out the steps described referring to FIGS. 3 to 18 will be described.

Formation steps in the memory cell region 1A and the peripheral circuit region 1B and structures formed by these steps are similar to those described referring to FIGS. 3 to 18. The capacitive element region 1C which will be described in the present modification example is a formation region of a capacitive element CD shown in FIG. 2.

In the manufacturing steps of the present modification example, first, a semiconductor substrate SB equipped with an element isolation region ST is provided by the step described referring to FIG. 1. A capacitive element to be formed in a later step in the capacitive element region 1C makes use of a portion of the semiconductor substrate SB as a lower electrode. Therefore, an n well or p well is formed in the main surface of the semiconductor substrate SB of the capacitive element region 1C.

The semiconductor substrate SB of the capacitive element region 1C has, in the main surface thereof, an element isolation region ST at an end portion of a capacitive element formation region. In the region having therein the element isolation region ST, a contact plug is coupled to an upper electrode of the capacitive element rightly above the element isolation region ST in a later step.

Then, by carrying out the step described referring to FIG. 2, insulating films IF1 to IF3 and an insulating film IF7 on the semiconductor substrate SB of the capacitive element region IC are formed as shown in FIG. 20. Then, a silicon film PS1 and an insulating film IF4 are formed successively on the semiconductor substrate SB. Similar to the insulating film IF2, the insulating film IF7 is formed, for example, by ISSG oxidation. This means that the insulating film IF7 has a film thickness greater than that of the insulating films IF1 and IF3. As a result, a stacked film included of the insulating film IF7, the silicon film PS1, and the insulating film IF4 is formed on the semiconductor substrate SB of the capacitive element region 1C.

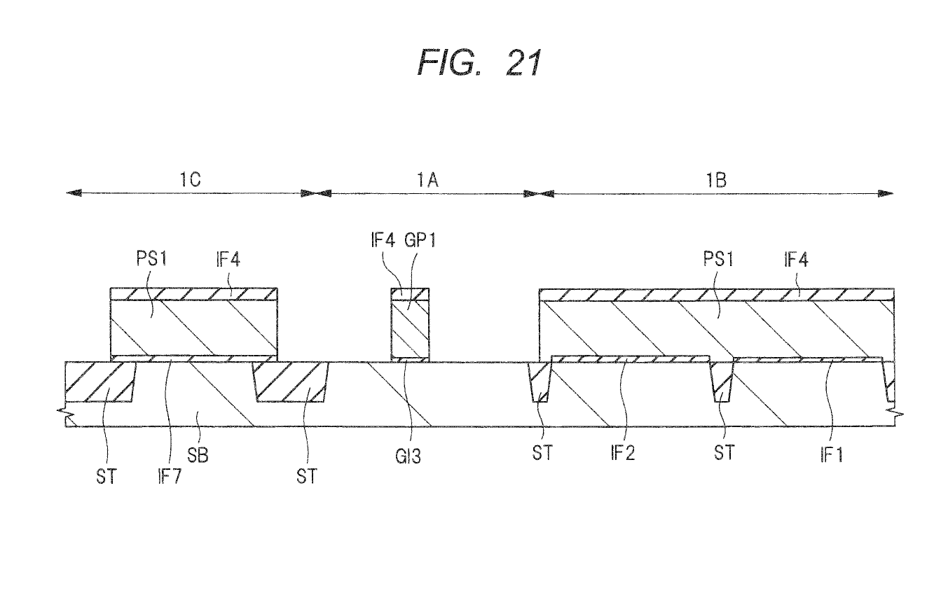

Next, as shown in FIG. 21, by carrying out steps similar to those described referring to FIG. 5, a gate pattern GP1 and a gate insulating film GI3 are formed in the memory cell region 1A and at the same time, the stacked film of the capacitive element region 1C is patterned.

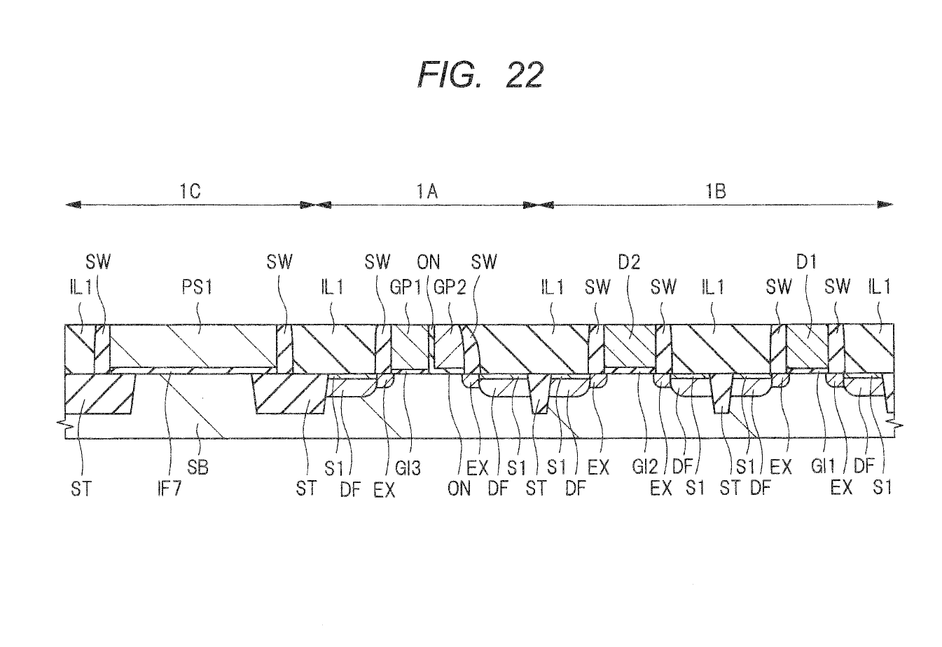

Next, as shown in FIG. 22, steps similar to those described referring to FIGS. 6 to 12 are carried out to form a sidewall SW on the side wall of the silicon film PS1 of the capacitive element region 1C to cover the silicon film PS1 with the interlayer insulating film IL1. Then, the upper surface of the silicon film PS1 is exposed by a polishing step. This means that the insulating film IL4 on the silicon film PS1 is removed. The height of the upper surface of the silicon film PS1 is substantially equal to the height of the gate patterns GP1 and GP2, and the dummy gate electrodes D1 and D2 or lower than that of the gate patterns GP1 and GP2, and the dummy gate electrodes D1 and D2.

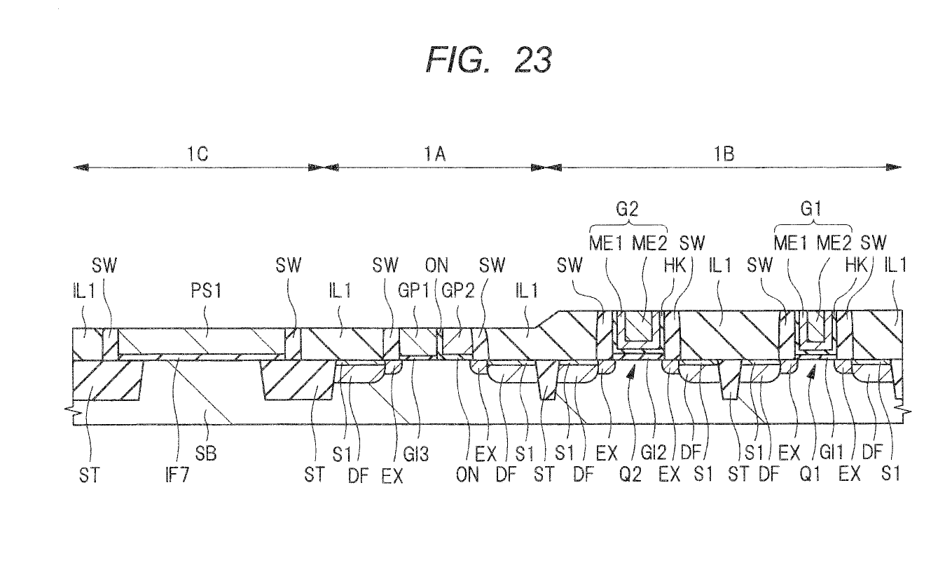

Next, as shown in FIG. 23, steps similar to those described referring to FIGS. 13 to 15 are performed to form gate electrodes G1 and G2, which are metal gate electrodes, in the peripheral circuit region 1B. At this time, by the polishing step described referring to FIG. 15, the upper surface of each of the silicon film PS1, the sidewall SW, and the interlayer insulating film IL1 in the capacitive element region 1C lowers relatively largely. This means that the height of the silicon film PS1 becomes almost equal to that of the gate patterns GP1 and GP2. This is because no metal film such as metal gate electrode is formed in the capacitive element region 1C and the polishing rate in this region becomes higher than that in the peripheral circuit region 1B having therein a metal gate electrode.

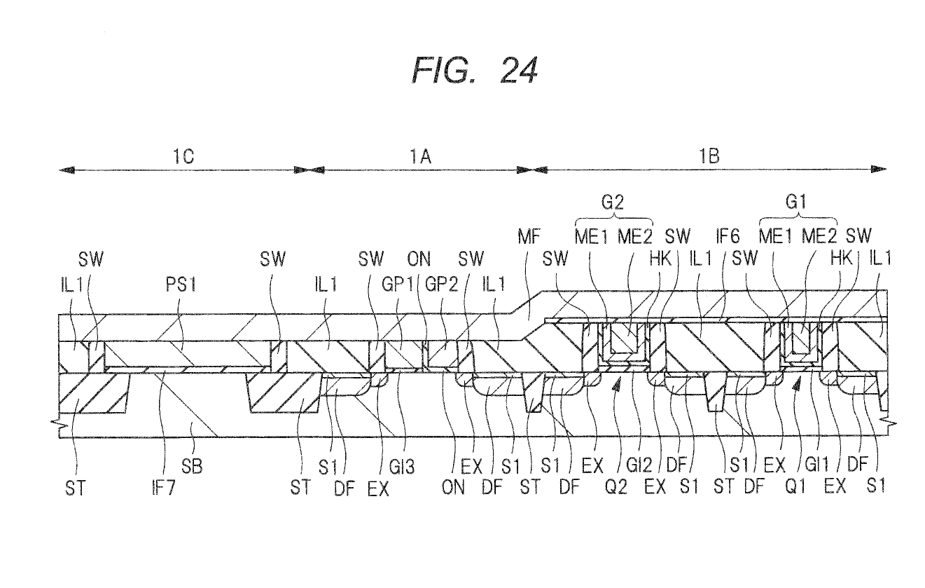

Next, as shown in FIG. 24, a step similar to that described referring to FIG. 16 is performed to cover the upper surface of the silicon film PS1 with a metal film MF. At this time, the upper surface of the silicon film PS1 is not covered with the insulating film IF6 and is contiguous to the metal film MF.

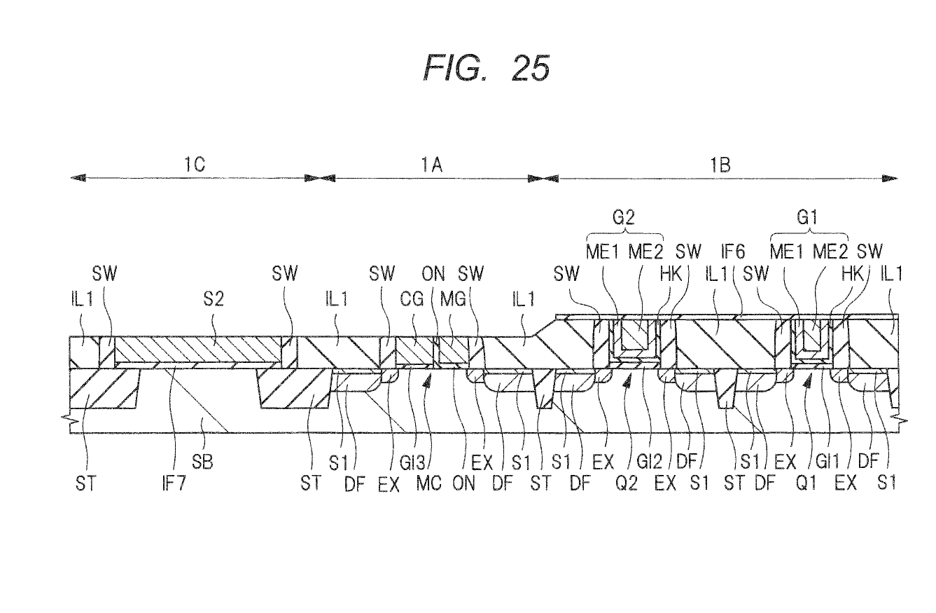

Next, as shown in FIG. 25, the salicide process is performed similarly to the step described referring to FIG. 17 to form fully silicided control gate electrode CG and memory gate electrode MG and at the same time, to fully silicide the silicon film PS1 of the capacitive element region 1C to form an upper electrode S2. An unnecessary portion of the metal film MF is then removed.

As a result, in the capacitive element region 1C, a capacitive element including the semiconductor substrate SB as a lower electrode and the upper electrode S2 which face with each other with the insulating film IF7 therebetween is formed. The upper electrode S2 is included of a silicide layer which has been silicided from the top surface to the bottom surface. This means that the upper electrode S2 does not have a semiconductor film unreacted with the metal film and the silicide layer constituting the upper electrode S2 and the insulating film IF7 rightly below the silicide layer have therebetween no semiconductor film. In other words, the silicide layer constituting the upper electrode S2 is contiguous to the upper surface of the insulating film IF7 in the capacitive element region IC.

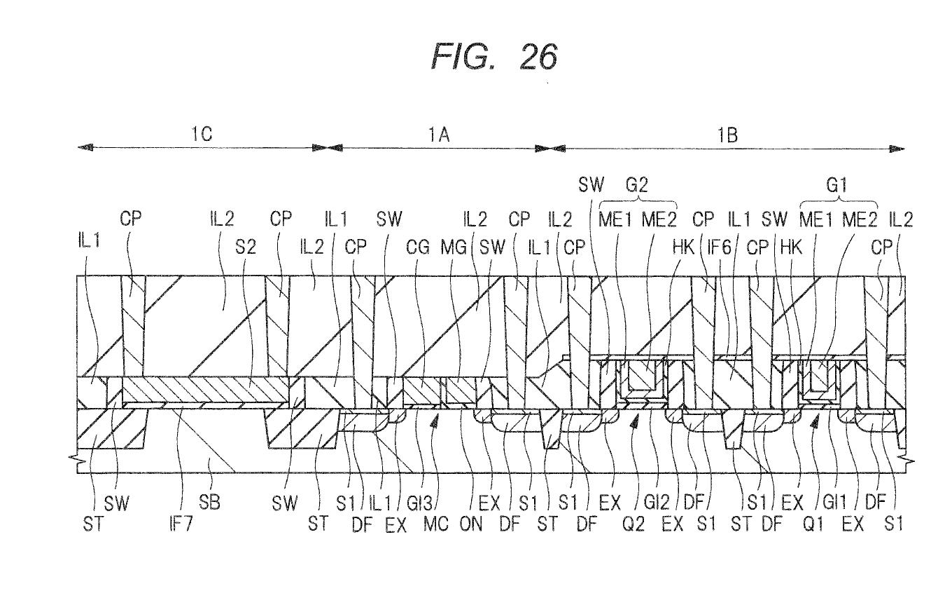

Next, as shown in FIG. 26, a step similar to that described referring to FIG. 17 is performed to form an interlayer insulating film IL2 and a plurality of contact plugs CP. In the capacitive element region 1C, the contact plug CP is coupled to the upper surface of the both end portions of the upper electrode S2 of the capacitive element. In the capacitive element region 1C, the contact plugs CP are coupled to the upper surface of the upper electrode S2 rightly above the region having therein the element isolation region ST. As a result, the semiconductor device of the present modification example is completed.

The present modification example can provide advantages similar to those described referring to FIGS. 1 to 18. In the capacitive element, depletion in the upper electrode S2 can be prevented by providing the upper electrode S2 as a fully silicided one. A semiconductor device having improved performance can be obtained by using the fully silicided upper electrode, compared with using the upper electrode S2 included of a semiconductor film. In addition, by using the fully silicided upper electrode S2 compared with using the upper electrode S2 included of a semiconductor film, the upper electrode has reduced resistance. As a result, the semiconductor device thus obtained can have improved performance.

Due to reduction in resistance of the upper electrode S2, when power is supplied to the upper electrode S2 at a plurality of positions, the distance between power supply portions to which the contact plugs CP are coupled can be widened. This enhances the degree of freedom in layout of the capacitive element and element isolation region ST. As a result, a miniaturized semiconductor device can be provided.

In the polishing step described referring to FIGS. 15 and 23, there may occur variation in the film thickness among plurality of silicon films PS1 in the capacitive element region 1C. In this case, silicidation of only a part of the upper portion of the silicon film PS1 may cause variation in film thickness of the silicide layer formed on each of the silicon films PS1 and further cause variation in performance among the capacitive elements.

In the present modification example, on the other hand, full silicidation of all the upper electrodes S2 contributes to prevent variations in performance attributable to variations in film thickness of the silicide layer. As a result, the semiconductor device thus obtained can have improved reliability.

The height of the upper surface of the upper electrode S2 is equal to the height of the upper surface of each of the control gate electrode CG and the memory gate electrode MG and is lower than the height of each of the gate electrodes G1 and G2. A distance between the wiring (not shown) on the interlayer insulating film IL2 and the upper electrode S2 can be increased, making it possible to prevent generation of parasitic capacitance between the wiring and the upper electrode S2.

As described above, the height of the upper electrode S2 formed by full silicidation by the salicide process is lower than the height of each of the gate electrodes G1 and G2 so that time necessary for heat treatment in the salicide process can be reduced. This makes it possible to prevent the insulating film HK of the peripheral circuit region 1B from being damaged.

In the present modification example, the layout area of the capacitive element can be decreased compared with the formation of the upper electrode of the capacitive element from a metal film (metal gate). The following is the reason of it. Described specifically, in the gate last process, in order to secure uniformity of the height of the metal gate, a severe limitation should be imposed on the maximum width of the metal gate or an occupancy ratio of the metal gate per unit area. The maximum width of the upper electrode must therefore be limited to 2 μm and the occupancy ratio must be limited to fall within a range of from 10 to 60%. In this case, in order to make the capacitance value achieved by the upper electrode included of a metal gate equivalent to that achieved by the upper electrode included of a polysilicon film, a plurality of capacitive elements having a small width must be arranged. This increases an area of the capacitive element, for example, by about 1.5 times.

In the present modification example, on the other hand, the upper electrode S2 can be formed according to a layout similar to that for the upper electrode included of a semiconductor film so that a predetermined capacitance can be achieved even if the layout area of the capacitive element is decreased. The semiconductor device thus obtained can therefore have improved performance.

### Second Modification Example

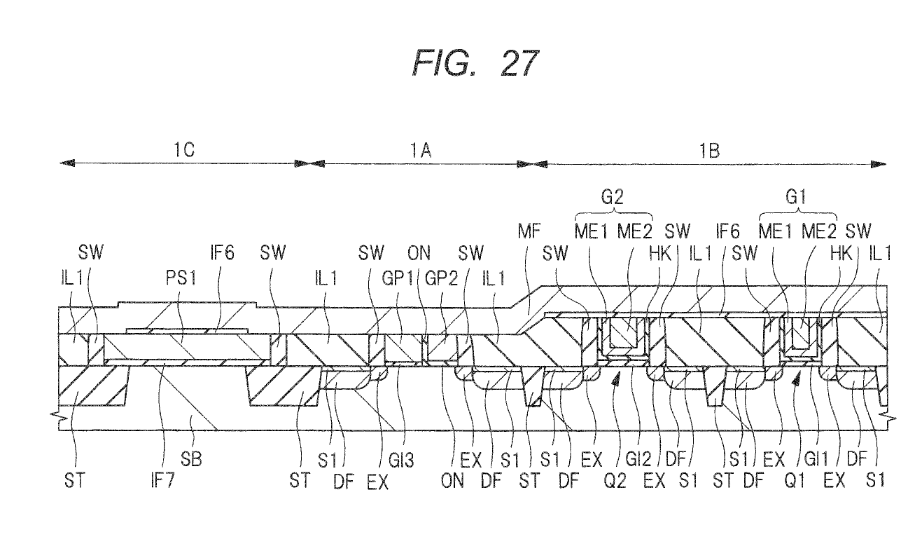

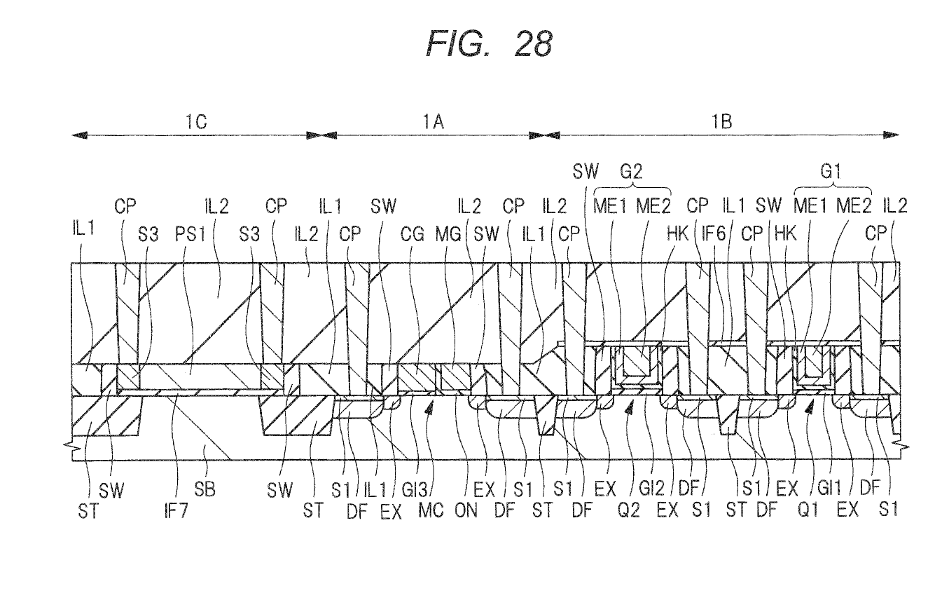

Next, manufacturing steps of a second modification example of the semiconductor device of the first embodiment will next be described referring to FIGS. 27 and 28. FIGS. 27 and 28 are cross-sectional views of the second modification example of the semiconductor device of the first embodiment during manufacturing steps. FIGS. 27 and 28 show, similar to FIGS. 20 to 26, the capacitive element region 1C, the memory cell region 1A, and the peripheral circuit region 1B in this order from the left side of the drawing. The present modification example is different from the first modification example in that the upper electrode of the capacitive element is not fully silicided but only the position of the upper electrode to which a contact plug is to be coupled is silicided from the top surface to the bottom surface of the upper electrode. Formation steps in the memory cell region 1A and the peripheral circuit region 1B and structures formed by these steps are similar to those described referring to FIGS. 3 to 18.

In the present modification example, manufacturing steps similar to those described referring to FIGS. 20 to 23 are carried out.

Next, as shown in FIG. 27, after formation of a plurality of insulating films IF6, a metal film MF is formed. A difference of this step from the step described referring to FIG. 24 is a formation region of the insulating film IF6. In this step, an insulating film IF6 that covers the gate electrodes G1 and G2 and an insulating film IF6 that covers a portion of the upper surface of the silicon film PS1 in the capacitive element region 1C are formed. The upper surface of the silicon film PS1 is exposed from the insulating film IF6 rightly above a region where a contact plug is to be coupled to an upper electrode of a capacitive element in a later step, that is, rightly above the element isolation region ST. In other words, the upper surface of the both end portions of the silicon film PS1 is exposed from the insulating film IF6 and contiguous to the metal film MF. The silicon film PS1 is, at the center portion of the upper surface thereof, covered with the insulating film IF6 and is not contiguous to the metal film MF.

Next, as shown in FIG. 28, steps similar to those described referring to FIGS. 25 to 26 are carried out to complete the semiconductor device shown in FIG. 28. When the silicon film PS1 in the capacitive element region 1C is silicided by reacting it with the metal film MF (refer to FIG. 27), a position not covered with the insulating film IF6 (refer to FIG. 27), that is, only the end portions of the silicon film PS1 are silicided. This means that the silicon film PS1 is silicided at both end portions thereof from the top surface to the bottom surface and a pair of silicide layers S3 is formed. Between these silicide layers S3, an unsilicided portion of the silicon film PS1 contiguous to the insulating film IF7 remains. In other words, the silicon film PS1 is, at the side walls thereof, contiguous to the silicide layer S3.

The silicon film PS1 and the silicide layer S3 in the capacitive element region 1C shown in FIG. 28 include an upper electrode of the capacitive element. The silicide layer S3 is provided at a power supply portion to the upper electrode. This means that the silicide layer S3 is provided rightly above the element isolation region ST and the contact plug CP is coupled to the upper surface of the silicide layer S3.

The present modification example can provide advantages similar to those described referring to FIGS. 1 to 18 in the memory cell MC constituting the MONOS memory and MISFETs Q1 and Q2. By fully siliciding the end portions of the upper electrode of the capacitive element and constituting the upper electrode other than the end portions thereof from the silicon film PS1, the insulating film IF7 can be prevented from being damaged by silicidation. In particular, a large voltage is applied to the electrode of the capacitive element compared with the control gate electrode CG and the memory gate electrode MG of the memory cell MC so that the insulating film IF7 of the capacitive element must keep high breakdown voltage. Therefore, by preventing the insulating film IF7 from damage, the semiconductor device thus obtained can have improved reliability.

In addition, compared with formation of a silicide layer only on the silicon film, silicidation of the end portions of the upper electrode from the top surface to the bottom surface can increase a contact area between the silicide layer S3 and the silicon film PS1. This leads to reduction in coupling resistance between the contact plug CP and the silicon film PS1. The semiconductor device thus obtained can therefore have improved performance.

Further, when power is supplied to the upper electrode at a plurality of positions, due to reduction in the resistance of the upper electrode, intervals of power supply portions to which the contact plug CP is to be coupled can be widened. This leads to enhancement of the degree of freedom in layout of the capacitive element and element isolation region ST and miniaturization of a semiconductor device.

Still further, even when variations in the film thickness occur among the silicon films PS1 in the capacitive element region 1C, full silicidation of the end portions of the upper electrode can prevent variations in performance of the capacitive element which will otherwise occur due to variations in the film thickness of the silicide layer. As a result, the semiconductor device thus obtained can have improved reliability.

The height of the upper surface of the upper electrode is equal to the height of the upper surface of each of the control gate electrode CG and the memory gate electrode MG and is lower than the height of each of the gate electrodes G1 and G2. This makes it possible to increase a separated distance between a wiring (not shown) on the interlayer insulating film IL2 and the upper electrode, thereby preventing generation of parasitic capacitance between the wiring and the upper electrode.

Further, since the upper electrode formed by siliciding the end portion of the silicon film PS1 from the top surface to the bottom surface as described above by the salicide process has a height lower than that of the gate electrodes G1 and G2, the insulating film HK in the peripheral circuit region 1B can be prevented from being damaged by the heat treatment in the salicide process.

In the present modification example, the upper electrode is included of the silicon film PS1 and the silicide layer S3. When predetermined capacitance must be achieved, the layout area of the capacitive element can be narrowed by using such an upper electrode compared with an upper electrode included of a metal gate. The semiconductor device thus obtained can have improved performance. This is because as described above in the first modification example, the layout of the metal gate is limited.

### Third Modification Example

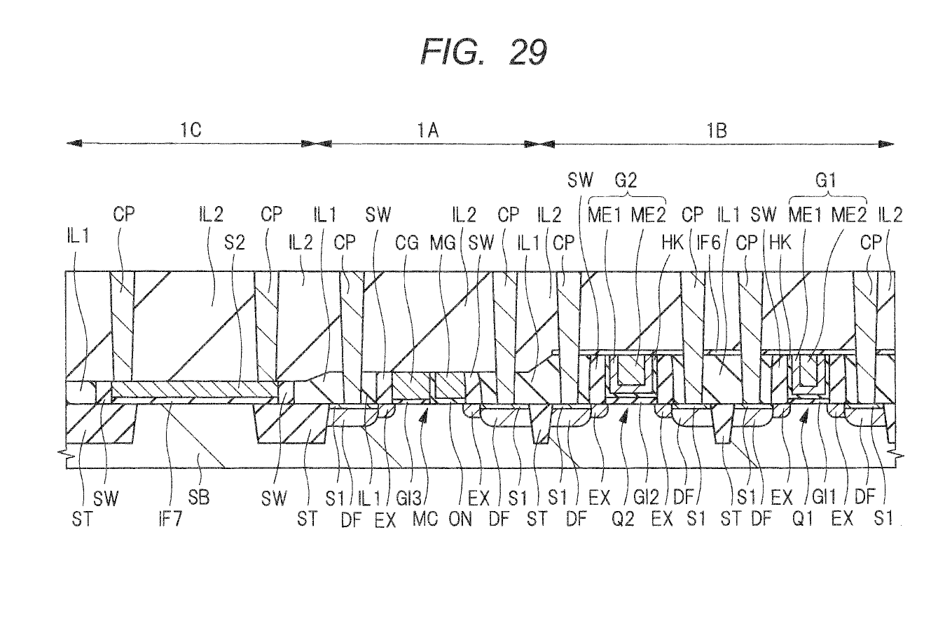

Next, a third modification example of the semiconductor device of the present embodiment will be described referring to FIG. 29. FIG. 29 is a cross-sectional view of the third modification example of the semiconductor device of the present embodiment. The structure shown in FIG. 29 is almost similar to that shown in FIG. 26, but is different from the structure shown in FIG. 26 in that the height of each of the interlayer insulating film IL1, the sidewall SW, and the upper electrode S2 in the capacitive element region 1C is lower.

The semiconductor device of the present modification example is manufactured by manufacturing steps similar to those of the first modification example. Here, a description will be made on the upper electrode S2 in the capacitive element region 1C having a height lower than that of each of the control gate electrode CG and the memory gate electrode MG.

When the polishing step, as described referring to FIG. 22, for exposing the upper surface of each of the silicon film PS1, the gate patterns GP1 and GP2, and the dummy gate electrodes D1 and D2 from the interlayer insulating film IL1 is performed, each film formed on the semiconductor substrate SB of the capacitive element region 1C is presumed to be polished more quickly and largely than each film in the memory cell region 1A and the peripheral circuit region 1B. This occurs because compared with the gate pattern in the memory cell region 1A and the peripheral circuit region 1B, the pattern of the silicon film PS1 in the capacitive element region 1C has an area larger and is more likely to be polished.

When the polishing step, as described referring to FIG. 25, for removing an unnecessary portion of the metal film MF on the interlayer insulating film IL1 is performed, each film formed on the semiconductor substrate SB of the capacitive element region 1C is presumed to be polished more quickly and largely than each film in the memory cell region 1A and the peripheral circuit region 1B. This occurs because the silicon film is polished more easily than the metal film and further, the silicon film PS1 in the capacitive element region 1C has an area larger than that of another gate pattern.

The height of each of the interlayer insulating film IL1, the sidewall SW, and the upper electrode S2 formed on the semiconductor substrate SB in the capacitive element region 1C becomes lower than the height of each of the interlayer insulating film IL1, the sidewall SW, the control gate electrode CG, and the memory gate electrode MG in the memory cell region 1A.

The present modification example can provide advantages similar to those of the first modification example. In addition to them, the present modification example provides the following advantage: since the height of the upper electrode S2 constituting the capacitive element is lower than the height of each of the control gate electrode CG and the memory gate electrode MG, parasitic capacitance between the upper electrode S2 and a wiring (not shown) on the interlayer insulating film IL2 can be reduced considerably.

### Fourth Modification Example

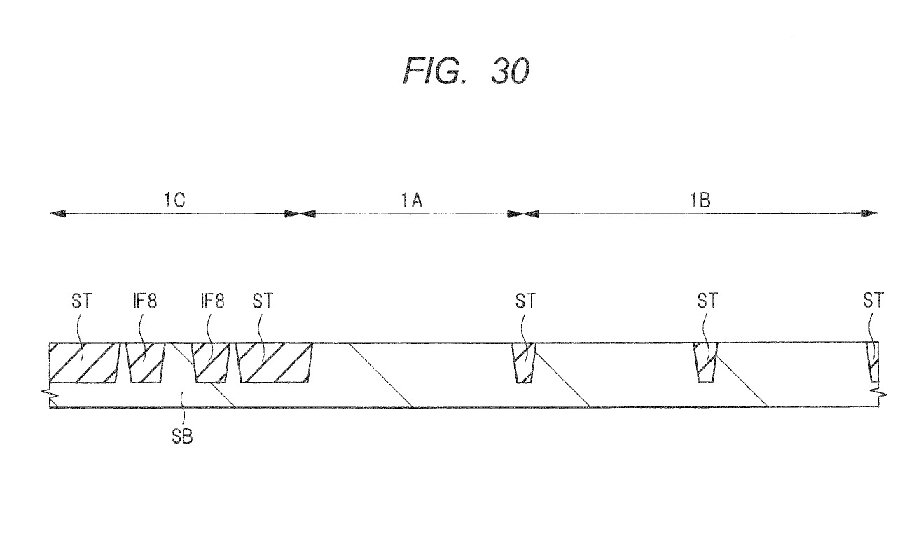

In the present modification example, formation of a trench type capacitive element will be described referring to FIGS. 30 to 33. FIGS. 30 to 33 are cross-sectional views of the fourth modification example of the semiconductor device of the present embodiment in the manufacturing steps thereof. FIGS. 30 to 33 each show, similar to FIGS. 20 to 26, the capacitive element region 1C, the memory cell region 1A, and the peripheral circuit region 1B. Formation steps in the memory cell region 1A and the peripheral circuit region 1B and structures formed by these steps are similar to those described referring to FIGS. 3 to 18.

In the manufacturing steps of the present modification example, first, a semiconductor substrate SB equipped with an element isolation region ST is provided by the step described referring to FIG. 1. A capacitive element to be formed in a later step in the capacitive element region 1C makes use of a portion of the semiconductor substrate SB as a lower electrode. Therefore, a p type or n type impurity is implanted into the upper surface of the semiconductor substrate SB in the capacitive element region 1C at a relatively large concentration. In the capacitive element region 1C, the semiconductor substrate SB has, in the main surface thereof, a pair of element isolation regions ST at end portions of a region in which the capacitive element is to be formed, that is, at power supply portions.

Here, a plurality of trenches is also formed in the upper surface of the semiconductor substrate in a region in which a capacitive element is to be formed in a later step and in a region between the pair of power supply portions and a plurality of insulating films IF8 having a structure similar to the element isolation region ST is formed in the trenches. The trenches and the insulating films IF8 are formed by STI used for the formation of the element isolation region ST. The insulating films IF8 are each included of, for example, a silicon oxide film.

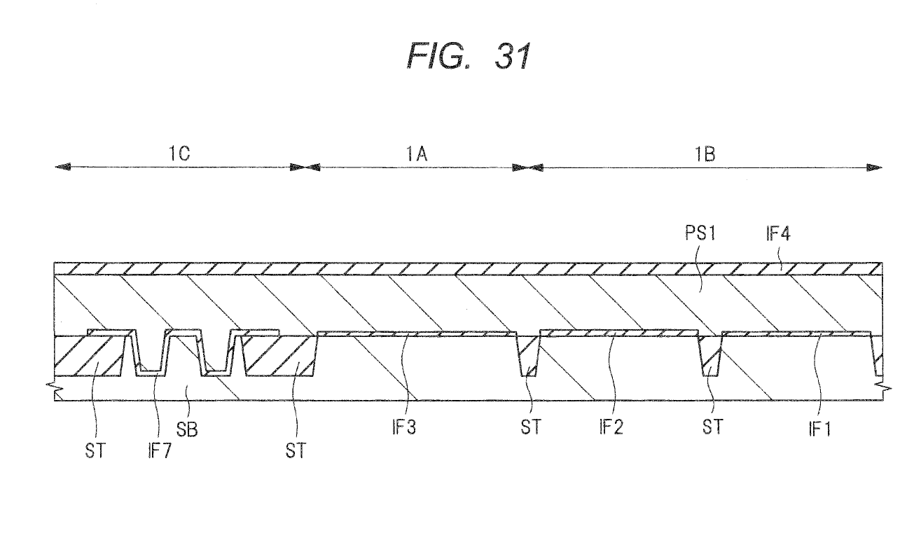

Next, as shown in FIG. 31, by using photolithography, the element isolation region ST is covered with a photoresist film and then, the insulating films IF8 are removed. Then, the step described referring to FIG. 20 is performed to form an insulating film IF7, a silicon film PS1, and an insulating film IL4 on the semiconductor substrate SB in the capacitive element region 1C. For example, the insulating film IL7 formed by ISSG oxidation covers the side wall and the bottom surface of a trench opened in regions from which the insulating films IF8 have been removed. This means that in the capacitive element region 1C, the silicon film PS1 and the semiconductor substrate SB have therebetween the insulating film IF7. The trench is completely filled with the insulating film IF7 and the silicon film PS1.

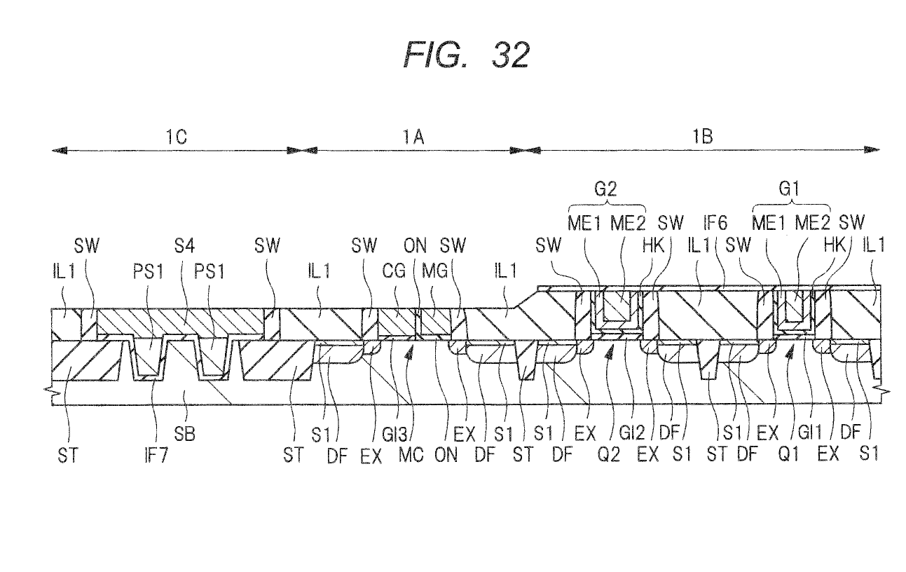

Next, as shown in FIG. 32, a portion of the silicon film PS1 in the capacitive element region 1C is silicided by carrying out steps similar to those described referring to FIGS. 21 to 25. The entirety of the silicon film PS1 in the capacitive element region 1C is not silicided but only a portion of the silicon film PS1 higher than the height of the uppermost surface of the semiconductor substrate SB is silicided to form a silicide layer S4 while a portion of the silicon film PS1 equal to or lower than the height of the uppermost surface of the semiconductor substrate SB is not silicided. This means that the silicide layer S4 and the silicon film PS1 lying thereunder have a boundary at a position higher than the uppermost surface of the semiconductor substrate SB.

To obtain such a structure, heat treatment in the salicide process is performed while adjusting heat treatment time so that the silicide layer S4 does not extend below the main surface of the semiconductor substrate SB. To the upper surface of the insulating film IF7 above the uppermost surface of the semiconductor substrate SB, the silicide layer S4 is contiguous.

By this step, an upper electrode of the capacitive element region 1C which is included of the silicide layer S4 and the silicon film PS1 coupled to the lower surface of the silicide layer S4 and embedded in the trench in the main surface of the semiconductor substrate SB is formed and a capacitive element including the upper electrode is formed. The trench has therein, via the insulating film IF7, the silicon film PS1, which is a portion of the upper electrode and extends from the side wall or bottom surface of the trench. The trench formed in the main surface of the semiconductor substrate SB and embedded with the upper electrode has a depth equal to that of the trench embedded with the element isolation region ST. The capacitive element of the present modification example is a trench type capacitive element having a structure in which the upper electrode embedded in the trench and the semiconductor substrate SB serving as the lower electrode are separated by the insulating film IF7.

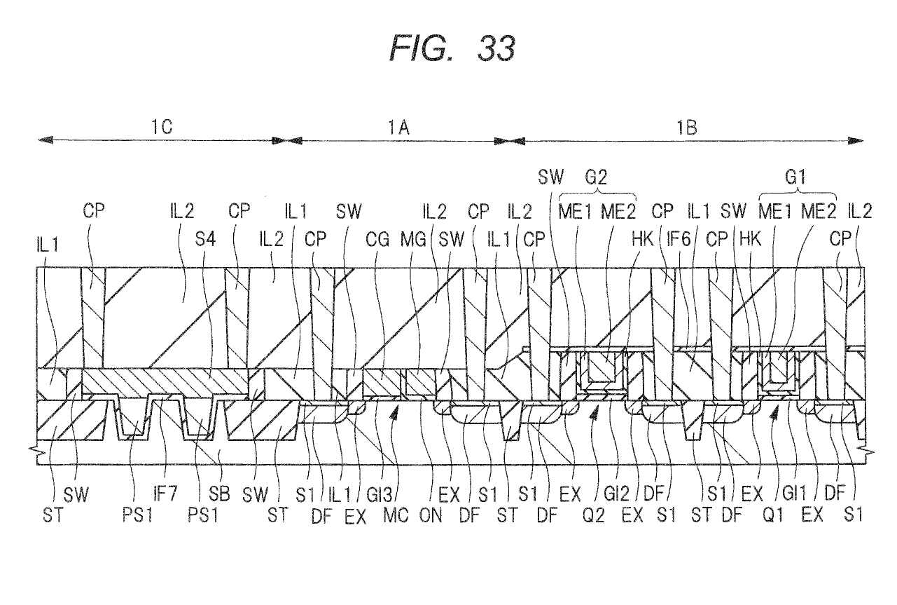

Next, as shown in FIG. 33, steps similar to those described referring to FIG. 26 are performed to couple a contact plug CP to the upper surface of the end portions of the silicide layer S4 constituting the upper electrode. As a result, the semiconductor device of the present modification example is completed.

In the present modification example, effectively large capacitance can be attained by providing a semiconductor device including MISFETs having a gate electrode formed by the gate last process with a trench type capacitive element. Among a plurality of kinds of capacitive elements, one is obtained by forming a lower electrode on the semiconductor substrate SB and then forming an upper electrode on the lower electrode via an insulating film. Examples of such a capacitive element include PIP (polysilicon insulator polysilicon). In PIP, large capacitance can be achieved by sterically stacking a plurality of electrodes.

The semiconductor device manufactured using the gate last process includes a step of polishing the upper portion of the gate electrode on the semiconductor substrate at least twice (refer to FIGS. 12 and 15) so that it is difficult to form a capacitive element by stacking an upper electrode on a lower electrode. A capacitive element obtained by placing an upper electrode having a flat bottom surface on a semiconductor substrate having a flat upper surface and generating capacitance between the upper electrode and the semiconductor substrate needs a large area for achieving sufficient capacitance.

In the trench type capacitive element described in the present modification example, on the other hand, a facing area of the upper electrode and the lower electrode (semiconductor substrate SB) can be widened by trenches. This means that the trench type capacitive element can generate capacitance even between electrodes facing with each other on the side surface of the trenches. Effectively large capacitance can be attained even when the area of the capacitive element is small in plan view. In short, the semiconductor device in the present modification example can have a small size and increased capacitance. This means that the semiconductor device can have improved performance.

The present modification example can provide advantages similar to those described referring to FIGS. 1 to 18 in the memory cell MC constituting the MONOS memory and the MISFETs Q1 and Q2. By siliciding the upper portion in the upper electrode and constituting the upper electrode in the trench in the main surface of the semiconductor substrate SB from the silicon film PS1, the insulating film IF7 can be prevented from being damaged by silicidation. As a result, the semiconductor device thus obtained can have improved reliability.

In addition, by siliciding not only the upper surface of the silicon film PS1 serving as the upper electrode but siliciding the semiconductor substrate SB up to a position in the vicinity of the uppermost surface thereof, that is, siliciding up to the upper surface of the insulating film IF7 on the semiconductor substrate SB, a proportion of the semiconductor film in the upper electrode can be decreased and thereby depletion in the upper electrode can be prevented. As a result, the semiconductor device can have improved performance.

Compared with the formation of a silicide layer only on the upper portion of the silicon film, silicidation from the upper surface of the upper electrode to the vicinity of the uppermost surface of the semiconductor substrate SB as in the present modification example can increase an occupancy ratio of the silicide layer S4 in the upper electrode. This leads to reduction in resistance of the upper electrode. As a result, the semiconductor device thus obtained has improved performance.

Due to the reduction in resistance of the upper electrode, power can be supplied to the upper electrode at a plurality of positions while enlarging intervals of the power supply portions to which the contact plug CP is coupled. This enhances the degree of freedom in the layout of the capacitive element and the element isolation region ST and contributes to miniaturization of a semiconductor device.

The height of the upper surface of the upper electrode is equal to the height of the upper surface of each of the control gate electrode CG and the memory gate electrode MG and is lower than the height of each of the gate electrodes G1 and G2. This makes it possible to increase a separated distance between a wiring (not shown) on the interlayer insulating film IL2 and the upper electrode, thereby preventing generation of parasitic capacitance between the wiring and the upper electrode.

Further, since the upper electrode formed by siliciding the silicon film PS1 up to the vicinity of the uppermost surface of the semiconductor substrate SB as described above by the salicide process has a height lower than that of the gate electrodes G1 and G2, the insulating film HK in the peripheral circuit region 1B can be prevented from being damaged by the heat treatment in the salicide process.

When predetermined capacitance must be achieved in the present modification example in which the upper electrode is included of the silicon film PS1 and the silicide layer S4, the layout area of the capacitive element can be narrowed compared with a case where the upper electrode is included of a metal gate. The semiconductor device thus obtained can therefore have improved performance. This is because as described in the first modification example, the layout of the metal gate is limited.

### Fifth Modification Example

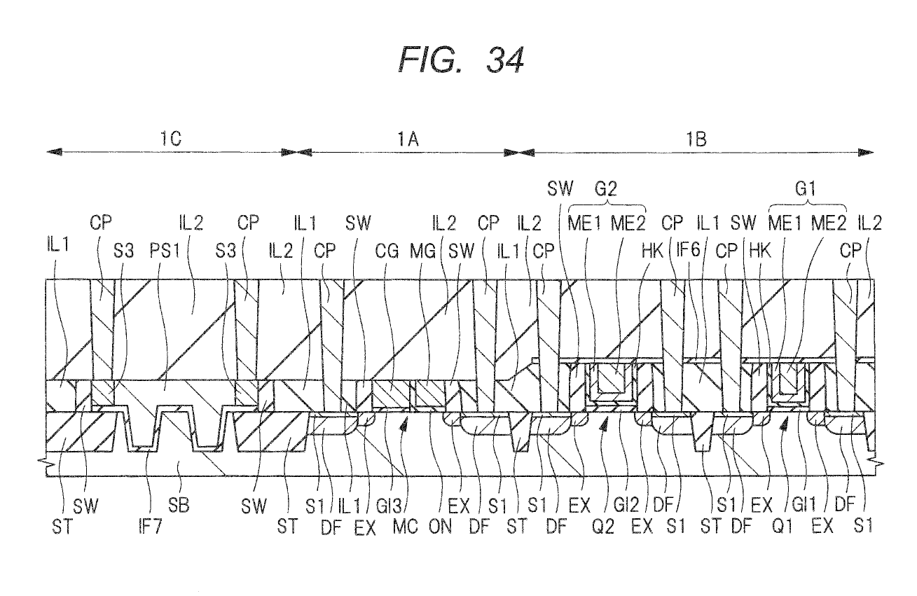

Next, a fifth modification example of the semiconductor device of the present embodiment will be described referring to FIG. 34. FIG. 34 is a cross-sectional view of the fifth modification example of the semiconductor device of the present embodiment. FIG. 34 shows a structure obtained by applying the constitution described in the above modification example in which only the end portions of the upper electrode of the capacitive element are silicided to the trench type capacitive element described in the fourth modification example.

Described specifically, in the present modification example, as described referring to FIGS. 30 and 21, a trench is formed in the capacitive element region 1C and a silicon film PS1 is formed in the trench via the insulating film IF7. During silicidation of the upper electrode in the capacitive element region 1C, as described referring to FIGS. 27 and 28, an insulating film IF6 that exposes the end portion of the upper surface of the silicon film PS1 and covers the center portion thereof is formed and then only the end portion of the silicon film PS1 is silicided to form a silicide layer S3.

In the present modification example, effectively large capacitance can be achieved by providing, with a trench type capacitive element, a semiconductor device including MISFETs having a gate electrode formed by the gate last process. As a result, the semiconductor device thus obtained can have improved performance.

The present modification example can provide advantages similar to those described referring to FIGS. 1 to 18 in the memory MC constituting the MONOS memory and MISFETs Q1 and Q2. In the capacitive element, by siliciding the end portion in the upper electrode except a region in the trench and constituting the upper electrode in the other region including the inside of the trench from the silicon film PS1, the insulating film IF7 can be prevented from being damaged by silicidation. As a result, the semiconductor device thus obtained can have improved reliability.

Compared with the formation of a silicide layer only on the upper portion of the silicon film, silicidation of the end portion of the upper electrode from the top surface to the bottom surface thereof as in the present modification example can enlarge a contact area between the silicide layer S3 and the silicon film PS1 and therefore, can reduce the coupling resistance between the contact plug CP and the silicon film PS1. As a result, the semiconductor device thus obtained can have improved performance.

Due to the reduction in resistance of the upper electrode, power can be supplied to the upper electrode at a plurality of positions while enlarging intervals of the power supply portions to which the contact plug CP is coupled. This enhances the degree of freedom in the layout of the capacitive element and the element isolation region ST and contributes to miniaturization of a semiconductor device.

The height of the upper surface of the upper electrode is equal to the height of the upper surface of each of the control gate electrode CG and the memory gate electrode MG and is lower than the height of each of the gate electrodes G1 and G2. This makes it possible to increase a separated distance between a wiring (not shown) on the interlayer insulating film IL2 and the upper electrode, thereby preventing generation of parasitic capacitance between the wiring and the upper electrode.

Further, since the upper electrode formed by siliciding the end portion of the silicon film PS1 up to the bottom surface thereof as described above by the salicide process has a height lower than that of the gate electrodes G1 and G2, the insulating film HK in the peripheral circuit region 1B can be prevented from being damaged by the heat treatment in the salicide process.

When predetermined capacitance must be achieved in the present modification example in which the upper electrode is included of the silicon film PS1 and the silicide layer S3, the layout area of the capacitive element can be narrowed compared with a case where the upper electrode is included of a metal gate. The semiconductor device thus obtained can therefore have improved performance. This is because as described in the first modification example, the layout of the metal gate is limited.

### Second Embodiment

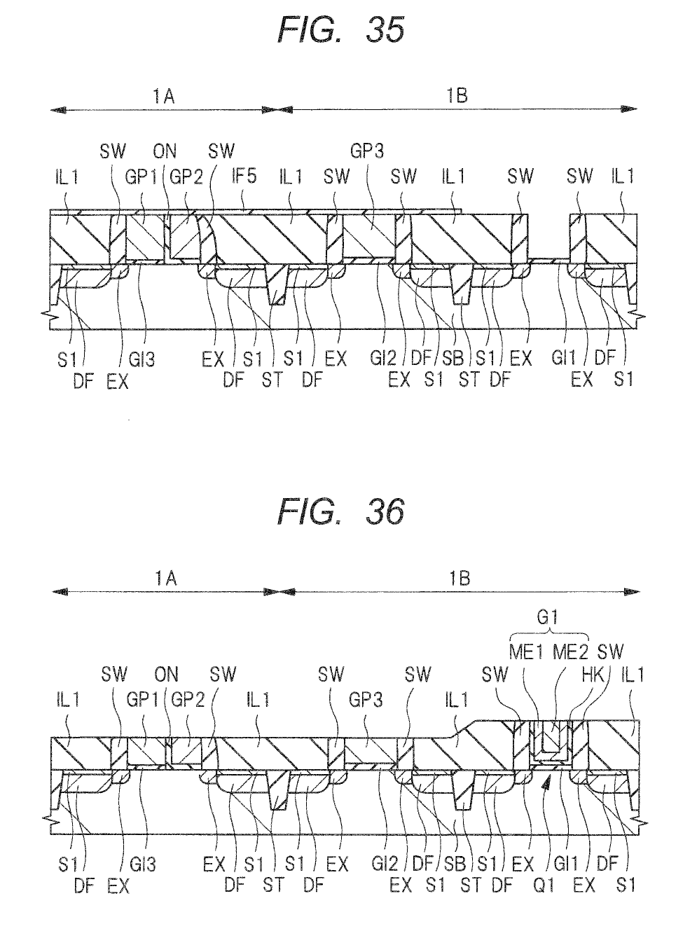

The present embodiment is different from the above-mentioned embodiment described referring to FIGS. 1 to 18. In it, a gate electrode of a high breakdown voltage MISFET in a peripheral circuit region is included of a silicide layer and at the same time, the gate electrode has a height equal to that of each of a control gate electrode and a memory gate electrode in a memory cell region and lower than that of a metal gate electrode constituting a low breakdown voltage MISFET in the peripheral circuit region. FIGS. 35 to 39 are cross-sectional views of the semiconductor device of the present embodiment during manufacturing steps thereof. Similar to FIGS. 3 to 18, FIGS. 35 to 39 show the memory cell region 1A and the peripheral circuit region 1B.

In the manufacturing steps of the semiconductor device of the present embodiment, first, steps similar to those described referring to FIGS. 3 to 12 are performed. It is however to be noted that a pattern provided on a gate insulating film GI2 in a high breakdown voltage MISFET formation region in the peripheral circuit region 1B is called not “dummy gate electrode D2” but “gate pattern GP3”.

Next, as shown in FIG. 35, a step corresponding to the step described referring to FIG. 13 is performed. Described specifically, after formation of an insulating film IF5 on the interlayer insulating film IL1, the dummy gate electrode D1 is removed. It is to be noted that the insulating film IF5 covers not only the memory cell region 1A but also the high breakdown voltage MISFET formation region in the peripheral circuit region 1B. This means that the insulating film IF5 formed before removal of the dummy gate electrode D1 covers the gate pattern GP3 as well as the gate patterns GP1 and GP2. The dummy gate electrode D1 is therefore removed from a low breakdown voltage MISFET formation region but the gate pattern GP3 remains without being removed. In this point, the present embodiment differs from First Embodiment.

Next, as shown in FIG. 36, a step similar to that described referring to FIGS. 14 and 15 is performed to form a gate electrode G1, which is a metal gate electrode, in a trench formed by removal of the dummy gate electrode D1. In the step of forming the metal gate electrode, an unnecessary portion of the metal film ME (refer to FIG. 14) on the interlayer insulating film IL1 is removed by polishing, for example, by CMP. At this time, the gate patterns GP1 to GP3 included of not a metal film but a silicon film have a height lower than that of the gate electrode G1 included of a metal film.

Described specifically, in the peripheral circuit region 1B, the height of each of the gate pattern GP3 and the sidewall SW and the interlayer insulating film IL1 in the vicinity thereof in the high breakdown voltage MISFET formation region becomes lower than the height of the upper surface of each of the gate electrode G1 of the low breakdown voltage MISFET Q1 and the sidewall SW and the interlayer insulating film IL1 in the vicinity thereof.

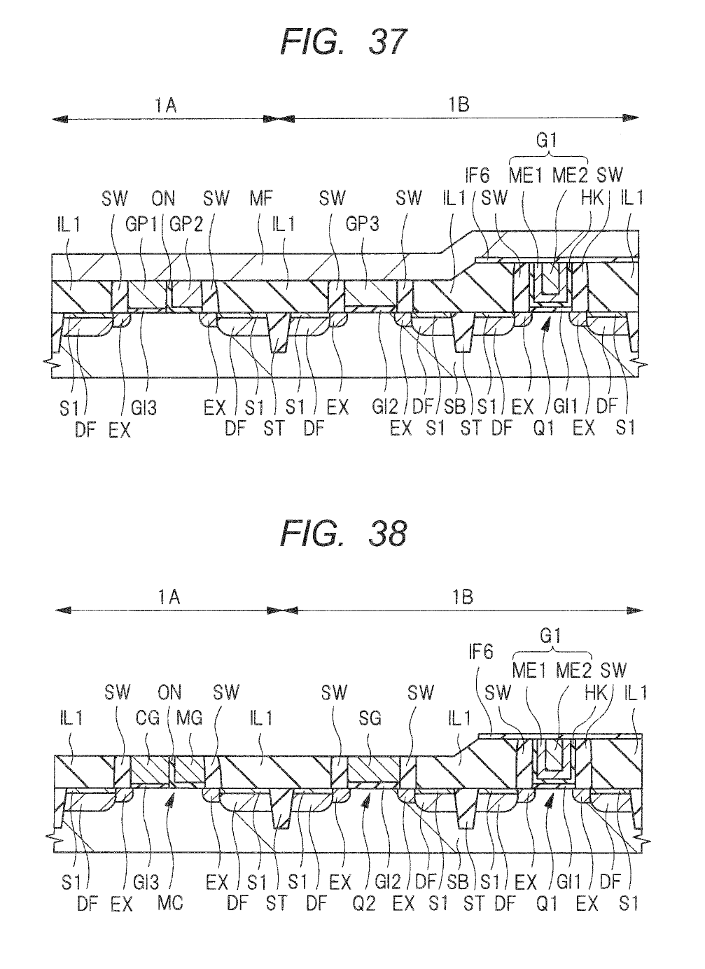

Next, as shown in FIG. 37, a step similar to that described referring to FIG. 16 is performed to successively form the pattern of an insulating film IF6 and a metal film MF on the interlayer insulating film ILL The insulating film IF6 has a structure different from the structure shown in FIG. 16 and it covers the gate electrode G1 for low breakdown voltage MISFET Q1 but does not cover the gate pattern GP3 for high breakdown voltage MISFET. The upper surface of the gate pattern GP3 is contiguous to the metal film MF.

Next, as shown in FIG. 38, a step similar to that described referring to FIG. 17 is performed to fully silicide the gate patterns GP1 to GP3. By this step, the gate pattern GP1 is silicided into a control gate electrode CG, the gate pattern GP2 is silicided into a memory gate electrode MG, and the gate pattern GP3 is silicided into a gate electrode SG. The gate electrode SG on the gate insulating film GI2 and a pair of source and drain regions in the main surface of the semiconductor substrate SB at the side of the gate electrode SG in the peripheral circuit region 1B include a high breakdown voltage MISFET Q2. The entirety of the gate electrode SG is included of a silicide layer. This means that the silicide layer constituting the gate electrode SG is contiguous to the upper surface of the gate insulating film GI2 rightly below the gate electrode SG.

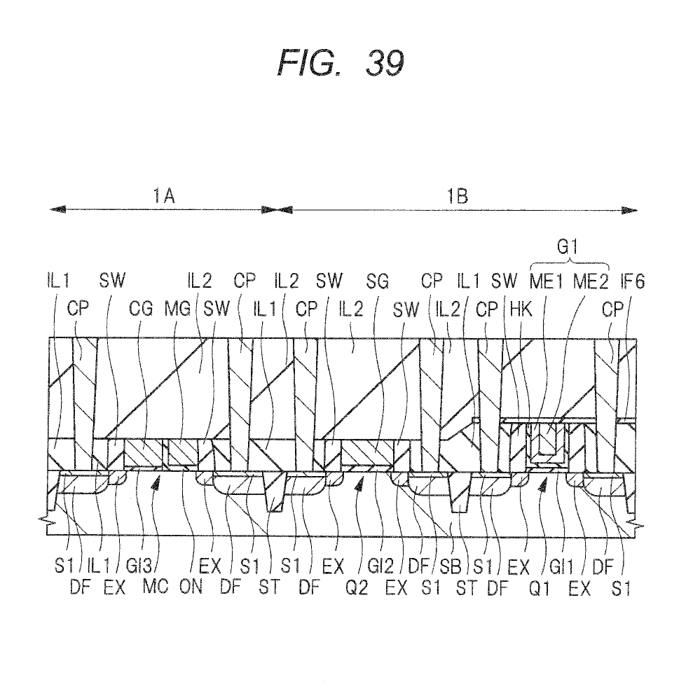

Next, as shown in FIG. 39, a step similar to that described referring to FIG. 18 is performed to form an interlayer insulating film IL2 and a plurality of contact plugs CP. As a result, the semiconductor device of the present embodiment is completed.

The present embodiment can provide advantages similar to those of First Embodiment in the memory cell MC in the memory cell region 1A and the low breakdown voltage MISFET Q1 in the peripheral circuit region 1B.

The present embodiment can stabilize the characteristics of the transistor compared with the case where the gate electrode of the high breakdown voltage MISFET Q2 is included of a metal gate electrode, because of the following reasons.

The gate insulating film of the high breakdown voltage MISFET is thicker than that of the low breakdown voltage MISFET so that in the semiconductor device using the gate last process for the formation of a gate electrode, the gate electrode of the high breakdown voltage MISFET has a reduced film thickness. In other words, when the gate last process is used and a step of polishing the upper surface of the gate electrode is performed, various gate electrodes thus polished have a substantially equal height so that with an increase in the thickness of the gate insulating film, the film thickness of the gate electrode of the high breakdown voltage MISFET having a thick gate insulating film decreases.

In this case, it is possible to include, like the gate electrode G1 shown in FIG. 39, the gate electrode of the high breakdown voltage MISFET from a stacked film of the metal film ME1 having a role of controlling the work function of the gate electrode G1 and the metal film ME2 formed on the metal film ME1 and having a role of reducing the resistance of the gate electrode G1. With a decrease in the film thickness of the gate electrode as described above, however, the film thickness of the gate electrode for high breakdown voltage MISFET is likely to vary largely in the manufacturing steps. Due to such variations in the film thickness of the gate electrode, the film thickness of the metal film ME1 necessary for controlling the work function of the gate electrode cannot be secured and stability which is the characteristics of the high breakdown voltage MISFET is damaged.

In the present embodiment, the gate electrode G2 of the high breakdown voltage MISFET Q2 is formed by fully siliciding a silicon film. This makes it possible to stabilize the characteristics of the MISFET Q2 even when the gate electrode G2 has a reduced film thickness. As a result, the semiconductor device thus obtained can have improved reliability.

The height of the upper surface of the gate electrode G2 is equal to the height of the upper surface of each of the control gate electrode CG and the memory gate electrode MG and is lower than the height of the gate electrode G1. This makes it possible to increase the separated distance between a wiring (not shown) on the interlayer insulating film IL2 and the gate electrode G2 and prevent generation of parasitic capacitance between the wiring and the gate electrode G2.

Inventions made by the present inventors have been described based on some embodiments thereof. It is needless to say that the invention is not limited to these embodiments but can be changed in various ways without departing from the gist of the invention.

What is claimed is:

1. A semiconductor device, comprising:
a semiconductor substrate; and
a memory cell having a first gate electrode including a first silicide layer formed over the semiconductor substrate via a first insulating film, a second gate electrode including a second silicide layer formed over a side wall of the first gate electrode via a second insulating film having therein a charge storage portion, and first source and drain regions formed in a main surface of the semiconductor substrate;
wherein the second gate electrode is formed over the semiconductor substrate via the second insulating film;
wherein the first silicide layer is contiguous to an upper surface of the first insulating film; and
wherein the second silicide layer is contiguous to an upper surface of the second insulating film between the second gate electrode and the semiconductor substrate.

2. The semiconductor device according to claim 1, further comprising:
a first field effect transistor including a third gate electrode which is a metal gate electrode formed over the semiconductor substrate via a third insulating film and second source and drain regions formed in the main surface of the semiconductor substrate;
wherein a height of an upper surface of each of the first gate electrode and the second gate electrode is lower than a height of an upper surface of the third gate electrode.

3. The semiconductor device according to claim 2,
wherein the first gate electrode and the second gate electrode, and the third gate electrode have therebetween a first interlayer insulating film;
wherein a second interlayer insulating film formed over the first interlayer insulating film covers the upper surface of each of the first to third gate electrodes; and
wherein a contact plug penetrating through the first interlayer insulating film and the second interlayer insulating film is coupled to the memory cell.

4. The semiconductor device according to claim 2,
wherein the third gate electrode has a first metal film formed over the third insulating film and a second metal film formed over the first metal film; and
wherein the second metal film has a side wall covered with the first metal film.

5. The semiconductor device according to claim 2,
wherein the third insulating film and the third gate electrode have therebetween a high dielectric constant insulating film having a dielectric constant higher than that of silicon nitride.

6. The semiconductor device according to claim 2, further comprising:
a second field effect transistor having a fourth gate electrode including a third silicide layer formed over the semiconductor substrate via a fourth insulating film and third source and drain regions formed in the main surface of the semiconductor substrate;
wherein the fourth insulating film has a film thickness greater than that of the third insulating film; and
wherein the third silicide layer is contiguous to an upper surface of the fourth insulating film.

7. The semiconductor device according to claim 6,
wherein a height of the upper surface of the fourth gate electrode is lower than the height of the upper surface of the third gate electrode.

8. The semiconductor device according to claim 1, further comprising an upper electrode including a fourth silicide layer over the semiconductor substrate via a fifth insulating film;
wherein the upper electrode and the semiconductor substrate insulated from each other via the fifth insulating film comprise a capacitive element; and
wherein the fourth silicide layer is contiguous to an upper surface of the fifth insulating film.

9. The semiconductor device according to claim 8,
wherein the upper electrode includes the fourth silicide layer formed at end portions of the upper electrode and a semiconductor film contiguous to a side wall of the fourth silicide layer and the upper surface of the fifth insulating film; and
wherein a contact plug is coupled to an upper surface of the fourth silicide layer.

10. The semiconductor device according to claim 8,
wherein the semiconductor substrate has a trench in an upper surface thereof;
wherein the trench is filled with the fifth insulating film and a portion of the upper electrode;
wherein the upper electrode has the fourth silicide layer and a semiconductor film formed in the trench; and
wherein the fourth silicide layer and the semiconductor film have therebetween a boundary over the uppermost surface of the semiconductor substrate.

11. The semiconductor device according to claim 8, further comprising:
a first field effect transistor including a third gate electrode which is a metal gate electrode formed over the semiconductor substrate via a third insulating film; and
second source and drain regions formed in the main surface of the semiconductor substrate,
wherein a height of an upper surface of the upper electrode is lower than a height of an upper surface of the third gate electrode.

12. The semiconductor device according to claim 8,
wherein a height of an upper surface of the upper electrode is lower than a height of an upper surface of each of the first gate electrode and the second gate electrode.

13. A method of manufacturing a semiconductor device equipped with a memory cell of a nonvolatile memory, comprising the steps of:
(a) providing a semiconductor substrate;
(b) forming a first gate pattern including a first semiconductor film over the semiconductor substrate via a first insulating film;
(c) successively forming a second insulating film having therein a charge storage portion and a second semiconductor film so as to cover a side wall of the first gate pattern and the semiconductor substrate adjacent to the side wall and exposed from the first insulating film;
(d) processing the second semiconductor film to form a second gate pattern including the second semiconductor film over the side wall of the first gate pattern via the second insulating film;
(e) forming an interlayer insulating film so as to cover the first gate pattern and the second gate pattern;
(f) polishing the interlayer insulating film to expose the first gate pattern and the second gate pattern; and
(g) after the step (f), siliciding the first gate pattern into a first silicide layer and siliciding the second gate pattern into a second silicide layer;
wherein the first silicide layer includes a first gate electrode for the memory cell and the second silicide layer includes a second gate electrode for the memory cell; and
wherein the first silicide layer is contiguous to an upper surface of the first insulating film and the second silicide layer is contiguous to an upper surface of the second insulating film.

14. The method of manufacturing a semiconductor device according to claim 13,
wherein the method further includes the step of:
(d1) before the step (e), forming a dummy gate electrode over the semiconductor substrate via a third insulating film;
wherein in the step (e), the interlayer insulating film covers the first gate pattern, the second gate pattern, and the dummy gate electrode;
wherein and in the step (f) the first gate pattern, the second gate pattern, and the dummy gate electrode are exposed;
wherein the method further includes the steps of:
(f1) after the step (f), removing the dummy gate electrode; and
(f2) after formation of a metal film over the semiconductor substrate including the inside of a first trench which is a region from which the dummy gate electrode has been removed in the step (f1), removing the metal film over the interlayer insulating film by polishing to form, in the first trench, a third gate electrode as a metal gate electrode for a first field effect transistor;
wherein a height of an upper surface of each of the first gate electrode and the second gate electrode is lower than a height of an upper surface of the third gate electrode.

15. The method of manufacturing a semiconductor device according to claim 14,
wherein in the step (d1), the dummy gate electrode is formed over the semiconductor substrate via the third insulating film and a third gate pattern is formed over the semiconductor substrate via a fourth insulating film having a film thickness greater than that of the third insulating film;
wherein in the step (e), the interlayer insulating film covers the first to third gate patterns and the dummy gate electrode;
wherein in the step (f), the first to third gate patterns and the dummy gate electrode are exposed;
wherein in the step (g), the first silicide layer and the second silicide layer are formed and the third gate pattern is silicided into a third silicide layer;
wherein the third silicide layer includes a fourth gate electrode for a second field effect transistor;
wherein the third silicide layer is contiguous to an upper surface of the fourth insulating film; and
wherein a height of an upper surface of the fourth gate electrode is lower than a height of an upper surface of the third gate electrode.

16. The method of manufacturing a semiconductor device according to claim 13, further comprising the step of:
(d2) before the step (e), forming a third semiconductor film over the semiconductor substrate via a fifth insulating film;
wherein in the step (e), the interlayer insulating film covers the first gate pattern, the second gate pattern, and the third semiconductor film;
wherein in the step (f), the first gate pattern, the second gate pattern, and the third semiconductor film are exposed;
wherein in the step (g), the first silicide layer and the second silicide layer are formed and the third semiconductor film is silicided into a fourth silicide layer;
wherein the fourth silicide layer includes an upper electrode for a capacitive element;
wherein the semiconductor substrate below the upper electrode includes a lower electrode for the capacitive element; and
wherein the fourth silicide layer is contiguous to an upper surface of the fifth insulating film.

17. The method of manufacturing a semiconductor device according to claim 16,
wherein in the step (g), the first silicide layer and the second silicide layer are formed and the fourth silicide layer is formed by siliciding an end portion of the third semiconductor film;
wherein the method further includes the step of:
(h) coupling a contact plug to an upper surface of the fourth silicide layer; and
wherein the upper electrode includes the fourth silicide layer and the third semiconductor film contiguous to a side wall of the fourth silicide layer and the upper surface of the fifth insulating film.

18. The method of manufacturing a semiconductor device according to claim 16, further comprising the step of:
(a1) before the step (b), forming a second trench in an upper surface of the semiconductor substrate;
wherein in the step (d2), the third semiconductor film is formed over the semiconductor substrate including the inside of the second trench via the fifth insulating film;
wherein in the step (g), the first silicide layer and the second silicide layer are formed and the fourth silicide layer is formed by siliciding the third semiconductor film over the uppermost surface of the semiconductor substrate;
wherein the upper electrode includes the fourth silicide layer and the third semiconductor film formed in the second trench; and
wherein the fourth silicide layer and the third semiconductor film have a boundary therebetween over the uppermost surface of the semiconductor substrate.

19. The method of manufacturing a semiconductor device according to claim 16,
wherein the method further includes the step of:
(d1) before the step (e), forming a dummy gate electrode over the semiconductor substrate via a third insulating film;
wherein in the step (e), the interlayer insulating film covers the first gate pattern, the second gate pattern, the third semiconductor film, and the dummy gate electrode;
wherein in the step (f), the first gate pattern, the second gate pattern, the third semiconductor film, and the dummy gate electrode are exposed;
wherein the method further includes the step of:
(f1) after the step (f), removing the dummy gate electrode; and
(f2) after formation of a metal film over the semiconductor substrate including the inside of a first trench which is a region from which the dummy gate electrode has been removed in the step (f1), removing the metal film over the interlayer insulating film by polishing to form, in the first trench, a third gate electrode as a metal gate electrode for a first field effect transistor;
wherein a height of an upper surface of the upper electrode is lower than a height of an upper surface of the third gate.
